(19) United States
(12) Patent Application Publication
(10) Pub. No.: US 2025/0254792 A1
(43) Pub. Date: Aug. 7, 2025

(54) RESIN COMPOSITION, PREPREG, RESIN SHEET, LAMINATE, METAL FOIL-CLAD LAMINATE, AND PRINTED WIRING BOARD

(71) Applicant: MITSUBISHI GAS CHEMICAL COMPANY, INC., Tokyo (JP)

(72) Inventors: Sayaka ITO, Tokyo (JP); Tatsuro TAKAMURA, Tokyo (JP); Naoki KASHIMA, Tokyo (JP); Tetsuro MIYAHIRA, Tokyo (JP); Takaaki OGASHIWA, Tokyo (JP)

(73) Assignee: MITSUBISHI GAS CHEMICAL COMPANY, INC., Tokyo (JP)

(21) Appl. No.: 18/846,740

(22) PCT Filed: Mar. 16, 2023
(86) PCT No.: PCT/JP2023/010221

§ 371 Date: Sep. 13, 2024

(30) Foreign Application Priority Data
Mar. 23, 2022 (JP) 2022-046294

(51) Int. Cl. H05K 1/03; B32B 15/08; B32B 15/20; C08G 8/32; C08G 65/48; C08J 5/18; C08J 5/24; C08K 9/02; C08K 9/08; C09K 5/14

(52) U.S. Cl. CPC H05K 1/036; B32B 15/08; B32B 15/20; C08G 8/32; C08G 65/485; C08J 5/18; C08J 5/249; C08K 9/02; C08K 9/08; C09K 5/14; H05K 1/0373; B32B 2264/107; B32B 2457/08; C08J 2361/04; C08J 2371/12; C08K 2201/001

(57) ABSTRACT

An object is to provide a resin composition having a high permittivity and a low dissipation factor, and having excellent heat resistance and moisture absorption and heat resistance, and suitably used for producing an insulation layer of a printed wiring board, and a prepreg, a resin sheet, a laminate, a metal foil-clad laminate, and a printed wiring board obtainable by using the resin composition. The resin composition of the present invention contains (A) a surface coated titanium oxide in which a mass reduction rate in heating from 30° C. to 300° C. at a heating rate of 10° C./min is 0.5 mass % or less, and (B) a thermosetting compound.

### TECHNICAL FIELD

The present invention relates to a resin composition, a prepreg, a resin sheet, a laminate, a metal foil-clad laminate, and a printed wiring board.

### BACKGROUND ART

In recent years, signal bands for information and telecommunication device such as PHS, and mobile phones, and CPU clock time of computers have reached the GHz band, and thus the frequency has been higher. A dielectric loss of an electrical signal is proportionate to the product of a square root of a relative permittivity and a dissipation factor of an insulation layer forming a circuit, and a frequency of the electrical signal. For this reason, the higher a frequency of a signal used, the greater a dielectric loss becomes. An increase in the dielectric loss dampens an electrical signal to undermine the reliability of the signal. It is necessary for preventing this to select a material having low permittivity and dissipation factor for an insulation layer.

On the other hand, for an insulation layer of a high frequency circuit, there are demands for formation of a delay circuit, impedance matching of a wiring board in a low impedance circuit, a finer wiring pattern, and a circuit more complex with a substrate having a built-in capacitor, and there is a case where an insulation layer with a higher permittivity is required. For this reason, electronic components in which an insulation layer having a high permittivity and a low dissipation factor is used have been proposed (e.g., Patent Document 1). An insulation layer having a high permittivity and a low dissipation factor is formed by dispersing a filler such as a ceramic powder and an insulated metal powder in a resin.

### CITATION LIST

### Patent Document

Patent Document 1: Japanese Patent Laid-Open No. 2000-91717

### SUMMARY OF INVENTION

### Technical Problem

For increasing the relative permittivity of an insulation layer, a filler having a high relative permittivity is required to be blended; however a dissipation factor also simultaneously increases, thereby posing the problem of a higher transmission loss of a higher frequency signal.

Additionally, the filler used for producing the insulation layer having a high permittivity and a low dissipation factor forms voids depending on the filler blended, and causes delamination when producing a laminate. For this reason, such a filler poses the problem of the poor dielectric characteristics (high permittivity and low dissipation factor) and heat resistance in a printed wiring board and the like.

Further, when an insulation layer has low moisture absorption and heat resistance, moisture contained in the insulation layer evaporates during reflow operation, thereby forming voids, and causing delamination during production of a laminate. For this reason, in the field of electronic materials where high reliability is required, the insulation layer is demanded to have excellent moisture absorption and heat resistance.

The present invention has been made to solve the problems described above and has aimed to provide a resin composition having a high permittivity and a low dissipation factor, and having excellent heat resistance and moisture absorption and heat resistance, and suitably used for producing an insulation layer of a printed wiring board, and a prepreg, a resin sheet, a laminate, a metal foil-clad laminate, and a printed wiring board obtainable by using the resin composition.

### Solution to Problem

The present inventors have conducted extensive studies to solve the above problems posed by the conventional technology, and have found that a specific resin composition can solve the above problems, whereby the present invention has been accomplished.

Specifically, the present invention is as follows.
[1]A resin composition containing:
   (A) a surface coated titanium oxide in which a mass reduction rate in heating from 30° C. to 300° C. at a heating rate of 10° C./min is 0.5 mass % or less, and
   (B) a thermosetting compound.
[2] The resin composition according to [1], wherein the surface coated titanium oxide (A) has an organic layer and/or an inorganic oxide layer on the surface of a titanium oxide particle.
[3] The resin composition according to [2], wherein the surface coated titanium oxide (A) further has the organic layer on the surface of the inorganic oxide layer.
[4] The resin composition according to [2] or [3], wherein a total amount of the organic layer and the inorganic oxide layer is 0.1 to 10 mass % based on 100 mass % of the surface coated titanium oxide (A).
[5] The resin composition according to any of [2] to [4], wherein the inorganic oxide layer is one or more selected from the group consisting of a layer containing silica, a layer containing zirconia, and a layer containing alumina.
[6] The resin composition according to any of [2] to [5], wherein the organic layer is a layer obtained by surface treating with an organosilicon compound.
[7] The resin composition according to [6], wherein the organosilicon compound contains one or more selected from the group consisting of silane coupling agents, organosilane, and organopolysiloxane.
[8] The resin composition according to any of [2] to [7], wherein a content of the titanium oxide in the surface coated titanium oxide (A) is 90 to 99.9 mass % based on 100 mass % of the surface coated titanium oxide (A).
[9] The resin composition according to any of [1] to [8], wherein a content of the surface coated titanium oxide (A) is 50 to 500 parts by mass, based on 100 parts by mass of a total resin solid content in the resin composition.
[10] The resin composition according to any of [1] to [9], wherein the thermosetting compound (B) contains one or more selected from the group consisting of maleimide compounds, epoxy compounds, modified polyphenylene ether compounds, cyanate ester compounds, phenol compounds, alkenyl-substituted nadiimide compounds, oxetane resins, benzoxazine compounds, and compounds having a polymerizable unsaturated group.
[11] The resin composition according to [10], wherein the maleimide compound contains one or more selected from the group consisting of bis(4-maleimidephenyl)methane, 2,2-bis(4-(4-maleimidephenoxy)-phenyl)propane, bis(3-ethyl-5-methyl-4-maleimidephenyl)methane, maleimide compounds represented by the following formula (1), and maleimide compounds represented by the following formula (2):

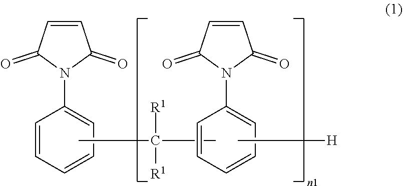

wherein R¹ each independently represents a hydrogen atom or a methyl group, and n1 is an integer of 1 to 10;

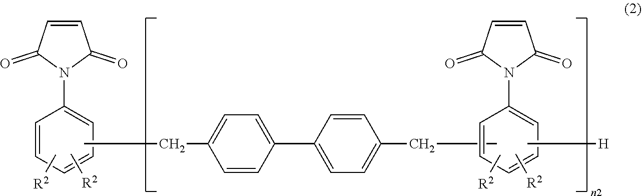

wherein R² each independently represents a hydrogen atom, an alkyl group having 1 to 5 carbon atoms, or a phenyl group, and n2 is an average value and represents 1<n2≤5.
[12] The resin composition according to [10] or [11], wherein the epoxy compound contains one or more selected from the group consisting of biphenyl aralkyl-type epoxy resins, naphthalene-type epoxy resins, and naphthylene ether-type epoxy resins.
[13] The resin composition according to any of [10] to [12], wherein the modified polyphenylene ether compound contains a compound represented by the following formula (3):

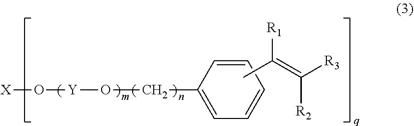

wherein X represents an aromatic group, —(Y—O)m- represents a polyphenylene ether moiety, R₁, R₂, and R₃ each independently represent a hydrogen atom, an alkyl group, an alkenyl group, or an alkynyl group, m represents an integer of 1 to 100, n represents an integer of 1 to 6, and q represents an integer of 1 to 4.
[14] The resin composition according to any of [10] to [13], wherein the cyanate ester compound contains one or more selected from the group consisting of phenol novolac-type cyanate ester compounds, naphthol aralkyl-type cyanate ester compounds, naphthylene ether-type cyanate ester compounds, xylene resin-type cyanate ester compounds, bisphenol M-type cyanate ester compounds, bisphenol A-type cyanate ester compounds, diallylbisphenol A-type cyanate ester compounds, bisphenol E-type cyanate ester compounds, bisphenol F-type cyanate ester compounds, and biphenyl aralkyl-type cyanate ester compounds, and prepolymers or polymers of these cyanate ester compounds.
[15] The resin composition according to any of [1] to [14], further containing a filler (C) different from the surface coated titanium oxide (A).
[16] The resin composition according to [15], wherein the filler (C) contains one or more selected from the group consisting of silica, alumina, barium titanate, strontium titanate, calcium titanate, aluminum nitride, boron nitride, boehmite, aluminum hydroxide, zinc molybdate, silicone rubber powder, and silicone-composite powder.
[17] The resin composition according to [15] or [16], wherein a content of the filler (C) is 50 to 300 parts by mass, based on 100 parts by mass of a total resin solid content in the resin composition.
[18] The resin composition according to any of [1] to [17], wherein the resin composition is for a printed wiring board.
[19]A prepreg, containing:
   a base material, and
   the resin composition according to any of [1] to [18] penetrating or coating the base material.
[20]A resin sheet containing the resin composition according to any of [1] to [18].
[21]A laminate containing one or more selected from the group consisting of the prepreg according to [19], and the resin sheet according to [20].
[22]A metal foil-clad laminate, containing:
   the laminate according to [21], and
   a metal foil disposed on one side or each of both sides of the laminate.
[23]A printed wiring board, containing an insulation layer, and a conductor layer disposed on one side or each of both sides of the insulation layer, wherein the insulation layer contains a cured product of the resin composition according to any of [1] to [18].

### Advantageous Effects of Invention

The resin composition of the present invention can accordingly provide a resin composition having a high permittivity and a low dissipation factor, and having excellent heat resistance and moisture absorption and heat resistance, and suitably used for producing an insulation layer of a printed wiring board; and a prepreg, a resin sheet, a laminate, a metal foil-clad laminate, and a printed wiring board obtainable by using the resin composition.

### DESCRIPTION OF EMBODIMENTS

Hereinafter, embodiments to carry out the present invention (hereinafter, referred to as the “present embodiment”) will be described in more detail. The following present embodiments are examples to illustrate the present invention and do not intend to limit the present invention to the contents below. The present invention can be carried out with appropriate modifications within the scope of the spirit thereof.

In the present embodiments, the “resin solid content” or the “resin solid content in the resin composition” refers to the resin components of the resin composition, excluding surface coated titanium oxide (A), the filler (C), additives (a silane coupling agent, a wetting and dispersing agent, a curing accelerator, and other components) and a solvent, unless otherwise noticed. The “100 parts by mass of the total resin solid content” or the “100 parts by mass of the total resin solid content in the resin composition” means that the total amount of the resin components of the resin composition, excluding surface coated titanium oxide (A), the filler (C), additives (a silane coupling agent, a wetting and dispersing agent, a curing accelerator, and other components) and a solvent, is regarded as 100 parts by mass.

### [Resin Composition]

The resin composition of the present embodiment contains: (A) a surface coated titanium oxide in which a mass reduction rate in heating from 30° C. to 300° C. at a heating rate of 10° C./min is 0.5 mass % or less, and (B) a thermosetting compound.

The present embodiment can provide a cured product having a high permittivity and a low dissipation factor, and having excellent heat resistance (solder heat resistance) and moisture absorption and heat resistance. That is, the resin composition of the present embodiment can be used for suitably producing a prepreg, a resin sheet, a laminate, a metal foil-clad laminate, and a printed wiring board having a high permittivity and a low dissipation factor during curing, and having excellent heat resistance and moisture absorption and heat resistance, and more suitably producing an insulation layer of a printed wiring board. Accordingly, the resin composition of the present embodiment is more suitably used for producing an insulation layer of a printed wiring board.

In particular, the present inventors have found that a resin composition containing (A) a surface coated titanium oxide in which a mass reduction rate in heating from 30° C. to 300° C. at a heating rate of 10° C./min is 0.5 mass % or less, and (B) a thermosetting resin is used in an insulation layer of a printed wiring board, whereby voids are less likely formed and delamination is less likely caused during production of a laminate during reflow operation. For this reason, according to the present embodiment, the close contact between an insulation layer and a conductor layer is excellent, whereby the printed wiring board or the like having favorable heat resistance and moisture absorption and heat resistance, and favorable dielectric characteristics (high permittivity and low dissipation factor) can be obtained. The reason is not clear but the present inventors infer as follows. That is, surface coated titanium oxide typically has a surface coating layer and thus relatively easily absorbs moisture in the atmosphere. Thus, in a cured product to be obtained with such surface coated titanium oxide, the absorbed moisture evaporates during reflow operation and voids are formed in an insulation layer. This phenomenon remarkably occurs in the case where such surface coated titanium oxide has an inorganic oxide layer as a surface coating layer. Additionally, when such surface coated titanium oxide has an organic layer as a surface coating layer, an organic content is easily decomposed by heat during reflow operation, and thus the organic content is volatilized and voids are further easily formed. When such surface coated titanium oxide has both an inorganic oxide layer and an organic layer, both evaporation of moisture and volatilization of an organic content occur. However, (A) a surface coated titanium oxide in which a mass reduction rate in heating from 30° C. to 300° C. at a heating rate of 10° C./min is 0.5 mass % or less can suitably inhibit both evaporation of moisture and volatilization of an organic content. Such surface coated titanium oxide (A) can be used together with thermosetting resin (B), thereby not only allowing for a high permittivity and a low dissipation factor and allowing for excellent heat resistance and moisture absorption and heat resistance, but also suitably inhibiting evaporation of moisture in the case where an inorganic oxide layer is included and volatilization of an organic content in the case where an organic layer is included. Accordingly, it is presumed by the present inventors that, according to the present embodiment, voids are less likely formed during reflow operation and delamination is less likely caused during production of a laminate. However, the mechanism is not limited to this.

### <Surface Coated Titanium Oxide (A)>

The resin composition of the present embodiment contains (A) a surface coated titanium oxide in which a mass reduction rate in heating from 30° C. to 300° C. at a heating rate of 10° C./min is 0.5 mass % or less.

The mass reduction rate in heating from 30° C. to 300° C. at a heating rate of 10° C./min is preferably 0.48 mass % or less, more preferably 0.45 mass % or less, and further preferably 0.43 mass %, in view of obtaining the resin composition having a higher permittivity and a lower dissipation factor and having more favorable heat resistance and moisture absorption and heat resistance. The lower limit is not particularly limited, and is, for example, 0% or more. The mass reduction rate can be measured with, for example, thermogravimetry (TG), but a specific measurement method can be referred to examples.

It is preferable in surface coated titanium oxide (A) that titanium oxide particles as the core of surface coated titanium oxide (A) (hereinafter, simply referred to as “titanium oxide particles” or “core particles”) have an organic layer and/or an inorganic oxide layer. Surface coated titanium oxides can be used singly for surface coated titanium oxide (A), or two or more surface coated titanium oxides with different particle sizes or surface conditions can also be used in combination.

The median particle size (D50) of surface coated titanium oxide (A) is preferably 0.1 to 5 μm, and more preferably 0.15 to 1 μm, in view of the dispersibility. Herein, the median particle size (D50) means the value at which a cumulative volume from smaller particles reaches 50% of the entire volume when a particle size distribution of a predetermined amount of a powder fed in a dispersion medium is measured using a laser diffraction scattering type particle size distribution analyzer. The median particle size (D50) can be calculated by measuring particle size distribution by a laser diffraction scattering method, but a specific measurement method can be referred to examples.

The shape of surface coated titanium oxide (A) is not particularly limited, and examples include scale-like shapes, spherical shapes, plate-like shapes, and amorphous shapes. The shape of surface coated titanium oxide (A) is preferably spherical in view of allowing for favorable dispersibility with thermosetting compound (B) described later, obtaining the resin composition having more excellent heat resistance and moisture absorption and heat resistance during curing, and favorable dielectric characteristics (high permittivity and low dissipation factor), and further obtaining the insulation layer having a more suitable surface hardness.

The relative permittivity of surface coated titanium oxide (A) is preferably 20 or more, and more preferably 25 or more. When a relative permittivity is 20 or more, there is a tendency that it is possible to obtain the insulation layer having a high relative permittivity. In the present embodiment, the relative permittivity of surface coated titanium oxide (A) is the value at 10 GHz measured by the cavity resonator method. In the present embodiment, the relative permittivity of surface coated titanium oxide (A) can be calculated using the Bruggeman formula (law of mixture).

The dissipation factor of surface coated titanium oxide (A) is preferably 0.01 or less, and more preferably 0.008 or less. When a dissipation factor is 0.01 or less, there is a tendency that it is possible to obtain the insulation layer having a low dissipation factor. In the present embodiment, the dissipation factor of surface coated titanium oxide (A) is the value at 10 GHz measured by the cavity resonator method. In the present embodiment, the dissipation factor of surface coated titanium oxide (A) can be calculated using the Bruggeman formula (law of mixture).

The total amount (coating amount) of the organic layer and the inorganic oxide layer in surface coated titanium oxide (A) is preferably, in total, 0.1 to 10 mass %, more preferably 1 to 8 mass %, and further preferably 1 to 4 mass %, based on 100 mass % of surface coated titanium oxide (A), in view of obtaining the printed wiring board or the like having more favorable heat resistance and moisture absorption and heat resistance, and favorable dielectric characteristics (high permittivity and low dissipation factor), more enhancing the close contact with resin components, more reducing the aggregation of surface coated titanium oxide (A) in the resin composition, more enhancing the dispersibility, and obtaining favorable dielectric characteristics (high permittivity and low dissipation factor) and heat resistance.

The content of the titanium oxide in surface coated titanium oxide (A) is preferably 90 to 99.9 mass %, more preferably 92 to 99 mass %, and further preferably 96 to 99 mass % based on 100 mass % of surface coated titanium oxide (A), in view of obtaining the printed wiring board or the like having more favorable heat resistance and moisture absorption and heat resistance, and favorable dielectric characteristics (high permittivity and low dissipation factor), more enhancing the close contact with resin components, more reducing the aggregation of surface coated titanium oxide (A) in the resin composition, more enhancing the dispersibility, and obtaining favorable dielectric characteristics (high permittivity and low dissipation factor) and heat resistance.

Examples of the core particle include titanium monoxide (TiO), dititanium trioxide (Ti₂O₃), and titanium dioxide (TiO₂). Of these, titanium dioxide is preferable. For titanium dioxide, those having rutile-type or anatase-type crystal structure are preferable, and those having rutile-type crystal structure are more preferable.

The median particle size (D50) of core particles is preferably 0.10 to 0.45 μm, and more preferably 0.15 to 0.25 μm, in view of dispersibility. In the present embodiment, the median particle size (D50) of core particles is determined from the average value of particle sizes of primary particles within a single particle.

Surface coated titanium oxide (A) can be typically obtained by coating the surface of core particles with an organic layer or an inorganic oxide layer by using a surface treatment agent. Further, an organic layer and/or an inorganic oxide layer may further coat the surface of the organic layer or the inorganic oxide layer coating the surface of core particles by using the surface treatment agent. It is preferable that surface coated titanium oxide (A) have an inorganic oxide layer coating the surface of core particles and further an organic layer on the surface of the inorganic oxide layer, in view of obtaining the printed wiring board or the like having more favorable heat resistance and moisture absorption and heat resistance, and favorable dielectric characteristics (high permittivity and low dissipation factor), more enhancing the close contact with resin components, more reducing the aggregation of surface coated titanium oxide (A) in the resin composition, more enhancing the dispersibility, and obtaining the cured product having favorable dielectric characteristics (high permittivity and low dissipation factor) and excellent heat resistance and moisture absorption and heat resistance. The coating method include inorganic treatments and organic treatments. The surface treatment agents can be used singly, or two or more thereof can also be used in combination.

Examples of the surface treatment agent used for an inorganic treatment include oxoacids, metal salts, oxides, hydroxides, and hydrates of oxides, of metals such as aluminum, silicon, zirconium, tin, titanium, antimony, zinc, cobalt, and manganese (examples of the oxoacids include silicic acid and aluminic acid, and examples of the metal salts include sodium silicate and sodium aluminate). Surface coated titanium oxide (A) obtained by an inorganic treatment has an inorganic oxide layer on the surface of titanium oxide particles, the surface of an inorganic oxide layer, or the surface of an organic layer to be described later.

Examples of the surface treatment agent used for an organic treatment include organosilicon compounds such as organosilane, silane coupling agent, and organopolysiloxane; organotitanium compounds such as titanate coupling agent; organic matters such as organic acid, polyol, and alkanolamine. Surface coated titanium oxide (A) to be obtained by an organic treatment has an organic layer on the surface of titanium oxide particles, the surface of an organic layer, or the surface of an inorganic oxide layer.

Examples of the organosilane include alkoxysilanes such as n-propyltrimethoxysilane, n-propyltriethoxysilane, hexyltrimethoxysilane, hexyltriethoxysilane, octyltrimethoxysilane, decyltrimethoxysilane, 3-chloropropyltriethoxysilane, phenyltriethoxysilane, and trifluoropropyltrimethoxysilane.

Examples of the silane coupling agent include aminosilanes such as 3-aminopropyltriethoxysilane, N-2-(aminoethyl)-3-aminopropyltriethoxysilane, and N-phenyl-3-aminopropyltrimethoxysilane; epoxysilanes such as 3-glycidoxypropyltrimethoxysilane and 2-(3,4-epoxycyclohexyl)ethyltrimethoxysilane; methacrylsilanes such as 3-(methacryloyloxypropyl)trimethoxysilane; vinylsilanes such as vinyltrimethoxysilane, vinyltriethoxysilane, and vinyltrichlorosilane; and mercaptosilanes such as 3-mercaptopropyltrimethoxysilane.

Organopolysiloxane is preferably silicone oil, which can form a more uniform organic layer. Examples of the silicone oil include alkyl silicone, alkyl hydrogen silicone, alkoxy silicone, and modified silicones.

Examples of the alkyl silicone include dimethyl silicone.

Examples of the alkyl hydrogen silicone include methyl hydrogen silicone and ethyl hydrogen silicone.

Alkoxy silicone is preferably a silicone compound containing an alkoxysilyl group, in which an alkoxy group is bonded to a silicon atom directly or via a divalent hydrocarbon group. Examples of such a silicone compound include straight-chain organopolysiloxanes having a straight-, cyclic-, network-, and partially branched-chain. Of these, straight-chain organopolysiloxanes are preferable, and organopolysiloxanes having a molecular structure in which an alkoxy group is directly bonded to the silicone backbone are more preferable. Examples of the alkoxy silicone include methoxy silicone, and ethoxy silicone.

Examples of the modified silicone include amino-modified silicone, epoxy-modified silicone, and mercapto-modified silicone.

Examples of the titanate coupling agent include isopropyl triisostearoyl titanate, isopropyl dimethacryl isostearoyl titanate, and isopropyl tridodecyl benzene sulfonyl titanate.

Examples of the organic acid include adipic acid, terephthalic acid, lauric acid, myristic acid, palmitic acid, stearic acid, polyhydroxystearic acid, oleic acid, salicylic acid, malic acid, and maleic acid, and metal salts thereof.

Examples of the polyol include trimethylolethane, trimethylolpropane, ditrimethylolpropane, trimethylolpropane ethoxylate, and pentaerythritol.

Examples of the alkanolamine include monoethanolamine, monopropanolamine, diethanolamine, dipropanolamine, triethanolamine, and tripropanolamine.

Surface coated titanium oxide (A) has an inorganic oxide layer on the surface of titanium oxide particles, wherein the inorganic oxide layer is preferably one or more selected from the group consisting of a layer containing silica, a layer containing zirconia, and a layer containing alumina, and the inorganic oxide layer is more preferably one or more selected from the group consisting of a layer containing silica and a layer containing alumina, in view of having favorable dispersibility with thermosetting compound (B), obtaining the resin composition having more excellent heat resistance and moisture absorption and heat resistance during curing, and more favorable dielectric characteristics (high permittivity and low dissipation factor), and further obtaining the insulation layer having an even more suitable surface hardness.

Surface coated titanium oxide (A) can have two or more inorganic oxide layers. When surface coated titanium oxide (A) has two or more inorganic oxide layers, it is preferable that the two or more inorganic oxide layers have the features such that the inorganic oxide layer positioned at the closer side to a titanium oxide particle can further inhibit the water absorption by mainly the titanium oxide particle which is the core particle, and such that the inorganic oxide layer positioned at the farther side from the titanium oxide particle can more enhance mainly the close contact with resin components, more reduce the aggregation of surface coated titanium oxide (A) in the resin composition, and more enhance the dispersibility.

From such a viewpoint, when surface coated titanium oxide (A) has two or more inorganic oxide layers, it is preferable that the inorganic oxide layer positioned at the closer side to the core particle be one or more selected from the group consisting of a layer containing silica and a layer containing zirconia, and that the inorganic oxide layer positioned at the farther side from the core particle be a layer containing alumina, and it is more preferable that the inorganic oxide layer positioned at the closer side to the core particle be a layer containing silica, and that the inorganic oxide layer positioned at the farther side to the core particle be a layer containing alumina.

The inorganic oxide layer is preferably, in total, 0.1 to 10 mass %, more preferably 0.3 to 7.5 mass %, further preferably 0.4 to 5.0 mass %, furthermore preferably 0.5 to 4.0 mass %, and even more preferably 0.5 to 3.3 mass %, based on 100 mass % of surface coated titanium oxide (A), in view of obtaining the printed wiring board or the like having more favorable heat resistance and moisture absorption and heat resistance, and more favorable dielectric characteristics (high permittivity and low dissipation factor), and obtaining the cured product having excellent heat resistance.

The inorganic oxide layer acts to inhibit the water absorption by titanium oxide, which is the core particle. On the other hand, silica, zirconia, and alumina, which are inorganic oxides constituting the inorganic oxide layer, are hydrous inorganic matters and have thus a comparatively high water absorption rate among inorganic oxides, whereby moisture tends to easily evaporate during reflow operation. The evaporated moisture causes to induce formation of voids in an insulation layer. Considering this, it is preferable that surface coated titanium oxide (A) have an organic layer on the surface of the inorganic oxide layer. The organic layer further reduces the water absorption of titanium oxide, which is the core particle, and the inorganic oxide layer, thereby further inhibiting the water absorption of the resin composition. For this reason, the moisture evaporation from the insulation layer during reflow operation can be inhibited. The organic layer more reduces the aggregation of surface coated titanium oxide (A) in the resin composition, thereby providing the effect of further enhancing the dispersibility.

The organic layer is preferably the layer obtained by surface treating with an organosilicon compound, in view of even more reducing the aggregation of surface coated titanium oxide (A) in the resin composition, even more enhancing the dispersibility, and reducing the water absorption rate of a laminate by more favorable water repellency.

The organosilicon compound preferably contains one or more selected from the group consisting of silane coupling agents, organosilane, and organopolysiloxane. The organic layer to be obtained by surface treating with these surface treatment agents is a layer having the siloxane structure. The layer having the siloxane structure tends to furthermore reduce the aggregation of surface coated titanium oxide (A) in the resin composition, furthermore enhance the dispersibility, and reduce the water absorption rate of a laminate by further excellent water repellency. The organopolysiloxane is preferably silicone oils, in view of forming a more uniform layer having the siloxane structure, and further providing the effects described above, and dimethyl silicone is more preferable among silicone oils. In this case, a surface treatment agent other than the above can be used as long as the organic layer becomes a layer having the siloxane structure.

The organic layer is, preferably, in total, 0.1 to 10 mass %, more preferably 0.5 to 7.5 mass %, further preferably 0.6 to 6.0 mass %, furthermore preferably 0.7 to 5.0 mass %, and even more preferably 0.7 to 3.5 mass %, based on 100 mass % of surface coated titanium oxide (A), in view of even more reducing the aggregation of surface coated titanium oxide (A) in the resin composition, and even more enhancing the dispersibility.

When surface coated titanium oxide (A) has the inorganic oxide layer and the organic layer, the coating layer of surface coated titanium oxide (A) can be a two-layer structure of the inorganic oxide layer and the organic layer. Such a layer structure provides the effect of inhibiting catalytic activity of titanium oxide (e.g., photocatalytic activity and metal catalytic activity) and the water repellency effect. In this case, the inorganic oxide layer is preferably one or more selected from the group consisting of a layer containing silica, a layer containing zirconia, and a layer containing alumina, and more preferably a layer containing alumina, in view of further inhibiting the catalytic activity of titanium oxide while further enhancing the affinity with the resin. The organic layer preferably has the siloxane structure due to excellent heat resistance and chemical stability. When such surface coated titanium oxide (A) is used, the water absorption of the titanium oxide can be even more inhibited, and the close contact with resin components even more enhances; thus, the aggregation of surface coated titanium oxide (A) in the resin composition can be even more reduced, thereby allowing for even better dispersibility with thermosetting compound (B). Accordingly, the resin composition having even more excellent heat resistance and moisture absorption and heat resistance during curing, and even more favorable dielectric characteristics (high permittivity and low dissipation factor) can be obtained, and further the insulation layer having an even more suitable surface hardness can be obtained.

Such surface coated titanium oxide (A) can be a commercial product. Examples of the commercial product include R-22L, and R-11P (all product names, SAKAI CHEMICAL INDUSTRY CO., LTD.).

When surface coated titanium oxide (A) has the inorganic oxide layer and the organic layer, it is preferable that the inorganic oxide layer positioned at the closer side to the core particle, the next inorganic oxide layer, and the organic layer positioned at the farthest side from the core particle be a layer containing silica, a layer containing alumina, and a layer having the siloxane structure, respectively. When such surface coated titanium oxide (A) is used, the water absorption of the titanium oxide can be even more inhibited, and the close contact with resin components even more enhances; thus, the aggregation of surface coated titanium oxide (A) in the resin composition can be even more reduced, thereby allowing for even better dispersibility with thermosetting compound (B). Accordingly, the resin composition having even more excellent heat resistance and moisture absorption and heat resistance during curing, and even more favorable dielectric characteristics (high permittivity and low dissipation factor) can be obtained, and further the insulation layer having an even more suitable surface hardness can be obtained.

Such surface coated titanium oxide (A) can be a commercial product. Examples of the commercial product include CR-63 (product name, ISHIHARA SANGYO KAISHA, LTD.).

The content of surface coated titanium oxide (A) is preferably 50 to 500 parts by mass, preferably 60 to 450 parts by mass, and more preferably 70 to 400 parts by mass, based on 100 parts by mass of the total resin solid content in the resin composition. When a content of surface coated titanium oxide (A) is within the above range, even more dispersibility with thermosetting compound (B) is obtained, and there is a tendency that it is possible to obtain the resin composition having even more excellent heat resistance and moisture absorption and heat resistance, and even more favorable dielectric characteristics (high permittivity and low dissipation factor) and further the insulation layer having a more suitable surface hardness.

### <Thermosetting Compound (B)>

The resin composition of the present embodiment contains thermosetting compound (B).

Thermosetting compound (B) is not particularly limited as long as the compound is a thermosetting compound or resin. The thermosetting compound (B) can be used singly, or two or more thereof can also be used in combination.

Thermosetting compound (B) preferably contains one or more thermosetting compounds or resins (hereinafter, also simply referred to as “thermosetting resin”) selected from the group consisting of maleimide compounds, epoxy compounds, modified polyphenylene ether compounds, cyanate ester compounds, phenol compounds, alkenyl-substituted nadiimide compounds, oxetane resins, benzoxazine compounds, and compounds having a polymerizable unsaturated group, in view of allowing surface coated titanium oxide (A) to be even more favorably dispersed, and obtaining the resin composition having even more excellent heat resistance and moisture absorption and heat resistance during curing, and having a more favorable dielectric characteristics (high permittivity and low dissipation factor). These thermosetting resins can be used singly, or two or more thereof can also be used in combination.

Thermosetting compound (B) is more preferably one or more selected from the group consisting of maleimide compounds, epoxy compounds, modified polyphenylene ether compounds, cyanate ester compounds, phenol compounds, and compounds having a polymerizable unsaturated group, and further preferably one or more selected from the group consisting of maleimide compounds, epoxy compounds, modified polyphenylene ether compounds, and cyanate ester compounds, in view of allowing surface coated titanium oxide (A) to be even more favorably dispersed, and obtaining the resin composition having even more excellent heat resistance and moisture absorption and heat resistance during curing, and having an even more favorable dielectric characteristics (high permittivity and low dissipation factor).

Surface coated titanium oxide (A) whose surface is coated thus can allow the electrophilicity due to Lewis acidity of titanium oxide to be suitably inhibited. Accordingly, even if surface coated titanium oxide (A) and thermosetting compound (B) are close to each other in the resin composition, polymerization of thermosetting compound (B) does not intendedly progress, and curing failure, an increase in viscosity, and the like can be prevented. Furthermore, surface coated titanium oxide (A) whose surface is coated thus can also allow the hydrolysis of thermosetting compound (B) to be suitably inhibited, and the amount of any unreacted functional group in an insulation layer can be decreased. Accordingly, the resin composition of the present embodiment suitably decreases the moisture content in an insulation layer during reflow operation, whereby voids are less likely formed and delamination is less likely caused during production of a laminate. Thermosetting compound (B) furthermore preferably contains one or more selected from the group consisting of maleimide compounds and cyanate ester compounds, in view of even more inhibiting progression of polymerization, and hydrolysis and thus obtaining the resin composition having even more excellent heat resistance and moisture absorption and heat resistance during curing, and even more favorable dielectric characteristics (high permittivity and low dissipation factor).

Surface coated titanium oxide (A) and thermosetting compound (B) are contained at preferably 30:70 to 90:10, more preferably 35:65 to 85:15, and further preferably 40:60 to 80:20, as represented by the mass ratio (surface coated titanium oxide (A):thermosetting compound (B)), in view of allowing surface coated titanium oxide (A) to be even more favorably dispersed, and obtaining the resin composition having even more excellent heat resistance and moisture absorption and heat resistance during curing, and even more favorable dielectric characteristics (high permittivity and low dissipation factor).

### (Maleimide Compound)

The resin composition of the present embodiment preferably contains a maleimide compound, in view of allowing surface coated titanium oxide (A) to be even more favorably dispersed, and obtaining the resin composition having even more excellent heat resistance and moisture absorption and heat resistance during curing, and having an even more favorable dielectric characteristics (high permittivity and low dissipation factor). The resin composition preferably contains a maleimide compound, also in view of remarkably obtaining the inhibition effect of progression of polymerization, and hydrolysis, due to surface coated titanium oxide (A). Furthermore, when the resin composition contains a maleimide compound, the close contact with surface coated titanium oxide (A) is even more enhanced, the aggregation of surface coated titanium oxide (A) in the resin composition can be more reduced, the dispersibility is more enhanced, and there is a tendency that it is possible to obtain favorable dielectric characteristics (high permittivity and low dissipation factor) and heat resistance.

For the maleimide compound, a known compound can be appropriately used as long as the compound has one or more maleimide groups in a molecule, and the kind thereof is not particularly limited. The number of maleimide groups in a molecule of the maleimide compound is one or more, and preferably two or more. The maleimide compounds can be used singly, or two or more thereof can also be used in combination.

Examples of the maleimide compound include N-phenylmaleimide, N-hydroxyphenylmaleimide, bis(4-maleimidephenyl)methane, 2,2-bis(4-(4-maleimidephenoxy)-phenyl)propane, bis(3,5-dimethyl-4-maleimidephenyl)methane, bis(3-ethyl-5-methyl-4-maleimidephenyl)methane, bis(3,5-diethyl-4-maleimidephenyl)methane, maleimide compounds represented by the formula (1), maleimide compounds represented by the formula (2), and prepolymers of the above maleimide compounds, and prepolymers of the maleimide compound and an amine compound.

Of these, the maleimide compound preferably contains one or more selected from the group consisting of bis(4-maleimidephenyl)methane, 2,2-bis(4-(4-maleimidephenoxy)-phenyl)propane, bis(3-ethyl-5-methyl-4-maleimidephenyl)methane, maleimide compounds represented by the formula (1), and maleimide compounds represented by the formula (2), and more preferably contains one or more selected from the group consisting of 2,2-bis(4-(4-maleimidephenoxy)-phenyl)propane and maleimide compounds represented by formula (2), in view of allowing surface coated titanium oxide (A) to be more favorably dispersed, and obtaining the resin composition having even more excellent heat resistance and moisture absorption and heat resistance during curing, and having an even more favorable dielectric characteristics (high permittivity and low dissipation factor), and further the insulation layer having a suitable surface hardness. Furthermore, when the resin composition contains such a maleimide compound, the close contact with surface coated titanium oxide (A) is more enhanced, the aggregation of surface coated titanium oxide (A) in the resin composition can be more reduced, the dispersibility is more enhanced, and there is a tendency that it is possible to obtain favorable dielectric characteristics (high permittivity and low dissipation factor) and heat resistance.

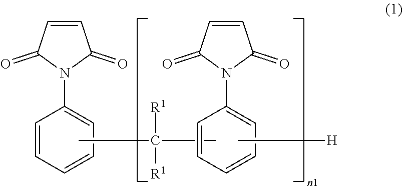

In the formula (1), R¹ each independently represents a hydrogen atom or a methyl group, and n1 is an integer of 1 to 10.

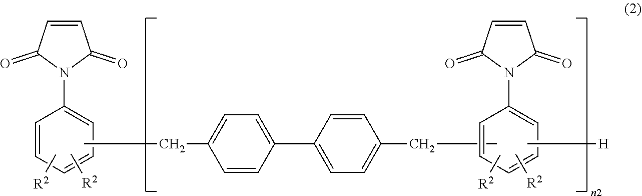

In the formula (2), R² each independently represents a hydrogen atom, an alkyl group having 1 to 5 carbon atoms, or a phenyl group, and n2 is an average value and represents 1<n2≤5.

The content of the maleimide compound is preferably 10 to 85 parts by mass, more preferably 15 to 80 parts by mass, further preferably 20 to 75 parts by mass, furthermore preferably 25 to 70 parts by mass, and further preferably 20 to 60 parts by mass, based on 100 parts by mass of the total resin solid content in the resin composition. When a content of the maleimide compound is within the above range, surface coated titanium oxide (A) is even more favorably dispersed, and there is a tendency that it is possible to obtain the resin composition having even more excellent heat resistance and moisture absorption and heat resistance during curing, and having further favorable dielectric characteristics (high permittivity and low dissipation factor) and further the insulation layer having a more suitable surface hardness. Furthermore, when a content of the maleimide compound is within the above range, the close contact with surface coated titanium oxide (A) is more enhanced, the aggregation of surface coated titanium oxide (A) in the resin composition can be more reduced, the dispersibility is more enhanced, and there is a tendency that it is possible to obtain favorable dielectric characteristics (high permittivity and low dissipation factor) and heat resistance.

Maleimide compounds can be a commercial product, or a product produced by a known method can also be used. Examples of the commercial products of the maleimide compound include BMI-70, BMI-80, and BMI-1000P (all product names, K.I Chemical Industry Co., Ltd.); BMI-3000, BMI-4000, BMI-5100, BMI-7000, and BMI-2300 (the maleimide compounds represented by the above formula (1), wherein R¹ is all hydrogen atoms, and n1 is an integer of 1 to 5) (all product names, Daiwa Kasei Industry Co., Ltd.); MIR-3000-70MT (product name, the maleimide compound represented by the above formula (2), wherein R² is all hydrogen atoms, and n2 is an average value and represents 1<n2≤5. Nippon Kayaku Co., Ltd.).

### (Epoxy Compound)

The resin composition of the present embodiment preferably contains an epoxy compound, in view of allowing surface coated titanium oxide (A) to be more favorably dispersed, and obtaining the resin composition having even more excellent heat resistance and moisture absorption and heat resistance during curing, and even more favorable dielectric characteristics (high permittivity and low dissipation factor). When the resin composition contains an epoxy compound, the close contact with surface coated titanium oxide (A) is more enhanced, the aggregation of surface coated titanium oxide (A) in the resin composition can be more reduced, the dispersibility is more enhanced, and there is a tendency that it is possible to obtain favorable dielectric characteristics (high permittivity and low dissipation factor) and heat resistance.

For the epoxy compound, a known compound can be appropriately used as long as the compound has one or more epoxy groups in a molecule, and the kind thereof is not particularly limited. The number of epoxy groups in a molecule of the epoxy compound is one or more, and preferably two or more. The epoxy compounds can be used singly, or two or more thereof can also be used in combination.

For epoxy compound, conventionally known epoxy compounds and epoxy resins can be used. Examples include biphenyl aralkyl-type epoxy resins, naphthalene-type epoxy resins, bisnaphthalene-type epoxy resins, polyfunctional phenol-type epoxy resins, naphthylene ether-type epoxy resins, phenol aralkyl-type epoxy resins, phenol novolac-type epoxy resins, cresol novolac-type epoxy resins, xylene novolac-type epoxy resins, naphthalene backbone-modified novolac-type epoxy resins, dicyclopentadiene novolac-type epoxy resins, biphenyl novolac-type epoxy resins, phenol aralkyl novolac-type epoxy resins, naphthol aralkyl novolac-type epoxy resins, aralkyl novolac-type epoxy resins, aromatic hydrocarbon formaldehyde-type epoxy compounds, anthraquinone-type epoxy compounds, anthracene-type epoxy resins, naphthol aralkyl-type epoxy compounds, dicyclopentadiene-type epoxy resins, ZYLOCK-type epoxy compounds, bisphenol A-type epoxy resins, bisphenol E-type epoxy resins, bisphenol F-type epoxy resins, bisphenol S-type epoxy resins, bisphenol A novolac-type epoxy resins, phenol-type epoxy compounds, biphenyl-type epoxy resins, aralkyl novolac-type epoxy resins, triazine backbone epoxy compounds, triglycidyl isocyanurate, alicyclic epoxy resins, polyol-type epoxy resins, glycidylamine, glycidyl-type ester resins, compounds obtained by epoxidating a double bond of a double bond-containing compound such as butadiene, such as butadiene, and compounds obtained by reaction of hydroxy group-containing silicone resins and epichlorohydrin.

Of these, the epoxy compound preferably contains one or more selected from the group consisting of biphenyl aralkyl-type epoxy resins, naphthalene-type epoxy resins, and naphthylene ether-type epoxy resins, and more preferably contains a naphthalene-type epoxy resin, in view of allowing surface coated titanium oxide (A) to be even more favorably dispersed, and obtaining the resin composition having even more excellent heat resistance and moisture absorption and heat resistance during curing, and even more favorable dielectric characteristics (high permittivity and low dissipation factor). When the resin composition further contains such an epoxy resin, the close contact with surface coated titanium oxide (A) is more enhanced, the aggregation of surface coated titanium oxide (A) in the resin composition can be more reduced, the dispersibility is more enhanced, and there is a tendency that it is possible to obtain favorable dielectric characteristics (high permittivity and low dissipation factor) and heat resistance.

Naphthalene-type epoxy resins can be a commercial product, and examples include EPICLON (registered trademark) EXA-4032-70M, and EPICLON (registered trademark) HP-4710 (all product names, DIC corporation).

The content of the epoxy compound is preferably 1 to 50 parts by mass, more preferably 5 to 40 parts by mass, and further preferably 10 to 30 parts by mass, based on 100 parts by mass of the total resin solid content in the resin composition. When a content of the epoxy compound is within the above range, the adhesivity, flexibility and the like tend to be more excellent. When a content of the epoxy resin is within the above range, surface coated titanium oxide (A) is even more favorably dispersed, and there is a tendency that it is possible to obtain the resin composition having even more excellent heat resistance and moisture absorption and heat resistance during curing, and further favorable dielectric characteristics (high permittivity and low dissipation factor), and the insulation layer having an even more suitable surface hardness. The close contact with surface coated titanium oxide (A) is more enhanced, the aggregation of surface coated titanium oxide (A) in the resin composition can be more reduced, the dispersibility is more enhanced, and there is a tendency that it is possible to obtain favorable dielectric characteristics (high permittivity and low dissipation factor) and heat resistance.

### (Modified Polyphenylene Ether Compound)

The resin composition of the present embodiment preferably contains a modified polyphenylene ether compound, in view of allowing surface coated titanium oxide (A) to be more favorably dispersed, and obtaining the resin composition having even more excellent heat resistance and moisture absorption and heat resistance during curing, and even more favorable dielectric characteristics (high permittivity and low dissipation factor). Furthermore, when the resin composition contains a modified polyphenylene ether compound, the close contact with surface coated titanium oxide (A) is more enhanced, the aggregation of surface coated titanium oxide (A) in the resin composition can be more reduced, the dispersibility is more enhanced, and there is a tendency that it is possible to obtain favorable dielectric characteristics (high permittivity and low dissipation factor) and heat resistance.

Herein, the “modified” of the modified polyphenylene ether compound means that the polyphenylene ether compound is substituted at a part or all of the terminals thereof with a reactive functional group such as a carbon-carbon unsaturated double bond. For the modified polyphenylene ether compound, a known compound can be appropriately used and is not particularly limited as long as the polyphenylene ether compound is modified at a part or all of the terminals thereof. The modified polyphenylene ether compounds can be used singly, or two or more thereof can also be used in combination.

Examples of the polyphenylene ether compound for the modified polyphenylene ether compound include polymers including at least one structural unit selected from the structural units represented by a formula (4), the structural units represented by a formula (5), and the structural units represented by a formula (6).

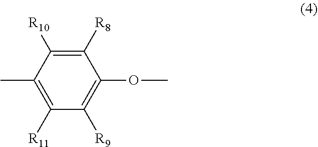

In the formula (4), R₈, R₉, R₁₀, and R₁₁ each independently represent an alkyl group having 6 or less carbon atoms, an aryl group, a halogen atom, or a hydrogen atom.

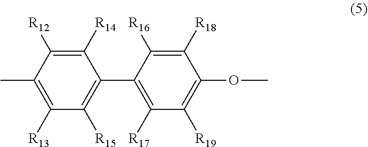

In the formula (5), R₁₂, R₁₃, R₁₄, R₁₈, and R₁₉ each independently represent an alkyl group having 6 or less carbon atoms or a phenyl group. R₁₅, R₁₆, and R₁₇ each independently represent a hydrogen atom, an alkyl group having 6 or less carbon atoms or a phenyl group.

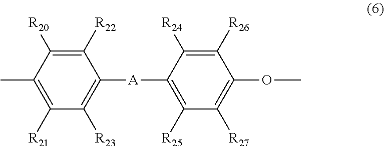

In the formula (6), R₂₀, R₂₁, R₂₂, R₂₃, R₂₄, R₂₅, R₂₆, and R₂₇ each independently represent a hydrogen atom, an alkyl group having 6 or less carbon atoms, or a phenyl group. -A- is a straight-, branched-, or cyclic-chain divalent hydrocarbon group having 20 or less carbon atoms.

In the formula (6), examples of the -A- include, but not limited to, divalent organic groups such as a methylene group, an ethylidene group, a 1-methylethylidene group, a 1,1-propylidene group, a 1,4-phenylenebis(1-methylethylidene) group, a 1,3-phenylenebis(1-methylethylidene) group, a cyclohexylidene group, a phenylmethylene group, a naphthylmethylene group, and a 1-phenylethylidene group.

The modified polyphenylene ether compound is preferably, for example, modified polyphenylene ether compounds having a functional group such as an ethylenically unsaturated group such as a vinyl benzyl group, an epoxy group, an amino group, a hydroxy group, a mercapto group, a carboxy group, a methacryl group, and a silyl group at a part or all of the terminals of a polyphenylene ether compound.

Examples of the modified polyphenylene ether compound whose terminal is a hydroxy group include SA90 (product name, SABIC innovative plastics).

Examples of polyphenylene ether whose terminal is a methacryl group include SA9000 (product name, SABIC innovative plastics).

The production method of the modified polyphenylene ether compound is not particularly limited as long as the effects of the present invention can be obtained. For example, the modified polyphenylene ether compound can be produced by the method described in U.S. Pat. No. 4,591,665.

The modified polyphenylene ether compound more preferably contain a modified polyphenylene ether compound having a terminal ethylenically unsaturated group. Examples of the ethylenically unsaturated group include alkenyl groups such as an ethenyl group, an allyl group, an acryl group, a methacryl group, a propenyl group, a butenyl group, a hexenyl group, and an octenyl group; cycloalkenyl groups such as cyclopentenyl group and a cyclohexenyl group; and alkenylaryl groups such as a vinyl benzyl group and a vinyl naphthyl group. Of these, a vinyl benzyl group is preferable.

The terminal ethylenically unsaturated group can be one or more, and can be the same functional group or different functional groups.

In view of allowing surface coated titanium oxide (A) to be even more favorably disperse, and obtaining the resin composition having even more excellent heat resistance and moisture absorption and heat resistance during curing, and even more favorable dielectric characteristics (high permittivity and low dissipation factor), the modified polyphenylene ether compound having a terminal ethylenically unsaturated group is preferably the compounds represented by a formula (3). Furthermore, when the resin composition contains such a compound represented by the formula (3), the close contact with surface coated titanium oxide (A) is more enhanced, the aggregation of surface coated titanium oxide (A) in the resin composition can be more reduced, the dispersibility is more enhanced, and there is a tendency that it is possible to obtain favorable dielectric characteristics (high permittivity and low dissipation factor) and heat resistance.

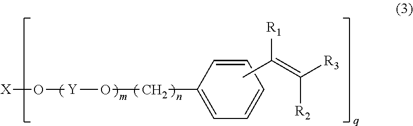

In the formula (3), X represents an aromatic group, and —(Y—O)ₘ— represents a polyphenylene ether moiety. R₁, R₂, and R₃ each independently represent a hydrogen atom, an alkyl group, an alkenyl group, or an alkynyl group, m represents an integer of 1 to 100, n represents an integer of 1 to 6, q represents an integer of 1 to 4. m is preferably an integer of 1 or more and 50 or less, and more preferably 1 or more and 30 or less. n is preferably an integer of 1 or more and 4 or less, more preferably 1 or 2, and ideally 1. q is preferably an integer of 1 or more and 3 or less, more preferably 1 or 2, and ideally 2.

Examples of the aromatic group represented by X in the formula (3) include groups formed by removing q hydrogen atoms from one ring structure selected from benzene ring structure, biphenyl ring structure, indenyl ring structure, and naphthalene ring structure (e.g., a phenylene group, a biphenylene group, indenylene group, and a naphthylene group). Of these, a biphenylene group is preferable.

The aromatic group represented by X herein can contain, for example, a group formed by bonding aryl groups via an oxygen atom, such as a diphenyl ether group, a group formed by bonding aryl groups via a carbonyl group, such as a benzophenone group, or a group formed by bonding aryl groups via an alkylene group, such as a 2,2-diphenylpropane group.

The aromatic group can be substituted with a general substituent such as an alkyl group (suitably an alkyl group having 1 to 6 carbon atoms, particularly a methyl group), an alkenyl group, an alkynyl group, and a halogen atom. However, the aromatic group is bonded to a polyphenylene ether moiety via an oxygen atom, and accordingly, the limit in the number of general substituents depends on the number of polyphenylene ether moieties.

For the polyphenylene ether moiety in the formula (3), the structural unit represented by the formula (4), the structural unit represented by the formula (5), and the structural unit represented by the formula (6) can be used. Of these, the structural unit represented by the formula (4) is more preferably contained.

The modified polyphenylene ether compound represented by the formula (3) preferably has a number average molecular weight of 500 or more and 7000 or less. The modified polyphenylene ether compound represented by the formula (3) having a minimum melt viscosity of 50000 Pa·s or less can be used. The modified polyphenylene ether compound represented by the formula (3) preferably has a number average molecular weight of 1000 or more and 7000 or less and a minimum melt viscosity of 50000 Pa·s or less, in view of allowing surface coated titanium oxide (A) to be even more favorably dispersed, and obtaining the resin composition having even more excellent heat resistance and moisture absorption and heat resistance during curing, and even more favorable dielectric characteristics (high permittivity and low dissipation factor).

The number average molecular weight is measured in accordance with a common method using gel permeation chromatography. The number average molecular weight is more preferably 1000 or more and 3000 or less.

The minimum melt viscosity is measured in accordance with a common method using a dynamic mechanical analyzer. The minimum melt viscosity is more preferably 500 Pa·s or more and 50000 Pa·s or less.

Among the compounds represented by the formula (3), the modified polyphenylene ether compound is preferably the compound represented by the following formula (7).

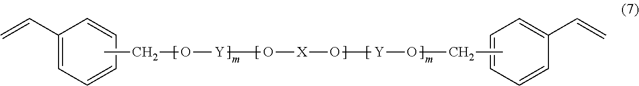

In the formula (7), X is an aromatic group, —(Y—O)ₘ— each independently represent a polyphenylene ether moiety, and m represents an integer of 1 to 100. m is preferably an integer of 1 or more and 50 or less, and more preferably an integer of 1 or more and 30 or less.

X, —(Y—O)ₘ—, and m in the formula (7) are the same as defined for in the formula (3).

X in the formula (3) and formula (7) is a formula (8), a formula (9), or a formula (10), and —(Y—O)ₘ— and —(O—Y)ₘ— in the formula (3) and the formula (7) are preferably a structure in which a formula (11) or a formula (12) is arranged, or a structure in which the formula (11) and the formula (12) are arranged in block or randomly.

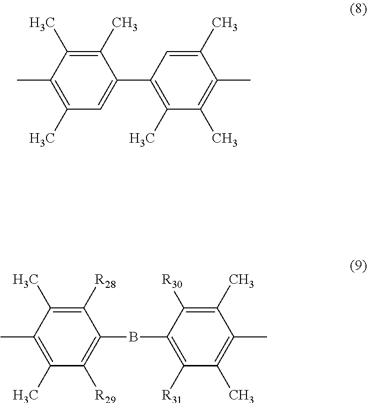

In the formula (9), R₂₈, R₂₉, R₃₀, and R₃₁ each independently represent a hydrogen atom or a methyl group. —B— is a straight-, branched-, or cyclic-chain divalent hydrocarbon group having 20 or less carbon atoms.

Specific examples of —B— include those that are the same as the specific examples of -A- in the formula (6).

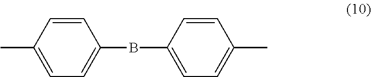

In the formula (10), —B— is a straight-, branched-, or cyclic-chain divalent hydrocarbon group having 20 or less carbon atoms.

Specific examples of —B— include those listed as the specific examples of -A- in the formula (6).

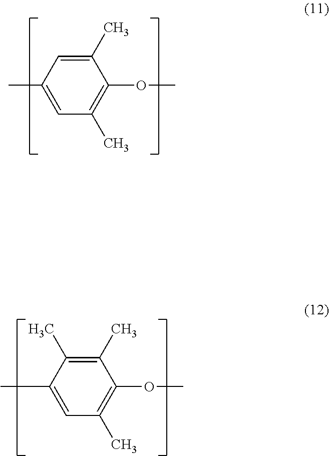

The production method of the modified polyphenylene ether compound having the structure represented by the formula (7) is not particularly limited, and, for example, such a modified polyphenylene ether compound can be produced by oxidatively coupling a bifunctional phenolic compound and a monofunctional phenolic compound to obtain a bifunctional phenylene ether oligomer, and vinylbenzyl-etherifying the terminal phenolic hydroxy group of the obtained bifunctional phenylene ether oligomer.

The modified polyphenylene ether compound can be a commercial product, and, for example, OPE-2St1200 (a polymer of the formula (7), wherein X in —(O—X—O)— is the structure represented by the formula (8), and —(O—Y)— and —(Y—O)— are the structure of the formula (11)) and OPE-2st2200 (a polymer of the formula (7), wherein X in —(O—X—O)— is the structure represented by the formula (8), and —(O—Y)— and —(Y—O)— are the structure of the formula (11)) (all product names, MITSUBISHI GAS CHEMICAL COMPANY, INC.) can be suitably used.

The content of the modified polyphenylene ether compound is preferably 1 to 50 parts by mass, more preferably 5 to 40 parts by mass, and further preferably 10 to 30 parts by mass, based on 100 parts by mass of the total resin solid content in the resin composition. When a content of the modified polyphenylene ether compound is within the above range, the low dissipation factor and the reactivity tend to even more enhance. When a content of the modified polyphenylene ether compound is within the above range, surface coated titanium oxide (A) is even more favorably dispersed, and there is a tendency that it is possible to obtain the resin composition having even more excellent heat resistance and moisture absorption and heat resistance during curing, and further favorable dielectric characteristics (high permittivity and low dissipation factor), and the insulation layer having an even more suitable surface hardness. The close contact with surface coated titanium oxide (A) is more enhanced, the aggregation of surface coated titanium oxide (A) in the resin composition can be more reduced, the dispersibility is more enhanced, and there is a tendency that it is possible to obtain favorable dielectric characteristics (high permittivity and low dissipation factor) and heat resistance.

### (Cyanate Ester Compound)

The resin composition of the present embodiment preferably contains a cyanate ester compound, in view of allowing surface coated titanium oxide (A) to be more favorably dispersed, and obtaining the resin composition having even more excellent heat resistance and moisture absorption and heat resistance during curing, and even more favorable dielectric characteristics (high permittivity and low dissipation factor). The resin composition preferably contains a cyanate ester compound, also in view of remarkably obtaining the inhibition effect of progression of polymerization, and hydrolysis, due to surface coated titanium oxide (A). Furthermore, when the resin composition contains a cyanate ester compound, the close contact with surface coated titanium oxide (A) is more enhanced, the aggregation of surface coated titanium oxide (A) in the resin composition can be more reduced, the dispersibility is more enhanced, and there is a tendency that it is possible to obtain favorable dielectric characteristics (high permittivity and low dissipation factor) and heat resistance. For the cyanate ester compound, a known compound can be appropriately used as long as the compound has a cyanate group directly bonded to two or more aromatic rings in the molecule (also referred to as “cyanate ester group”, or “cyanate group”). The cyanate ester compounds can be used singly, or two or more thereof can also be used in combination.

Examples of such a cyanate ester compound include phenol novolac-type cyanate ester compounds, cresol novolac-type cyanate ester compounds, naphthalene ring-containing novolac-type cyanate ester compounds, allyl group-containing novolac-type cyanate ester compounds, naphthol aralkyl-type cyanate ester compounds, naphthylene ether-type cyanate ester compounds, xylene resin-type cyanate ester compounds, bisphenol M-type cyanate ester compounds, bisphenol A-type cyanate ester compounds, diallylbisphenol A-type cyanate ester compounds, bisphenol E-type cyanate ester compounds, bisphenol F-type cyanate ester compounds, biphenyl aralkyl-type cyanate ester compounds, bis(3,3-dimethyl-4-cyanatephenyl)methane, 1,3-dicyanatebenzene, 1,4-dicyanatebenzene, 1,3,5-tricyanatebenzene, 1,3-dicyanatenaphthalene, 1,4-dicyanatenaphthalene, 1,6-dicyanatenaphthalene, 1,8-dicyanatenaphthalene, 2,6-dicyanatenaphthalene, 2,7-dicyanatenaphthalene, 1,3,6-tricyanatenaphthalene, 4,4′-dicyanatebiphenyl, bis(4-cyanatephenyl)ether, bis(4-cyanatephenyl)thioether, and bis(4-cyanatephenyl)sulfone. These cyanate ester compounds can be made into prepolymers or polymers of cyanate ester compounds.

Of these, in view of allowing surface coated titanium oxide (A) to be still more dispersed, and obtaining the resin composition having further excellent heat resistance and moisture absorption and heat resistance during curing, and further favorable dielectric characteristics (high permittivity and low dissipation factor), and further the insulation layer having a more suitable surface hardness, the cyanate ester compound preferably contains one or more selected from the group consisting of phenol novolac-type cyanate ester compounds, naphthol aralkyl-type cyanate ester compounds, naphthylene ether-type cyanate ester compounds, xylene resin-type cyanate ester compounds, bisphenol M-type cyanate ester compounds, bisphenol A-type cyanate ester compounds, diallylbisphenol A-type cyanate ester compounds, bisphenol E-type cyanate ester compounds, bisphenol F-type cyanate ester compounds, and biphenyl aralkyl-type cyanate ester compounds, and prepolymers or polymers of these cyanate ester compounds, and is more preferably a naphthol aralkyl-type cyanate ester compound. Furthermore, when the resin composition contains such a cyanate ester compound, the close contact with surface coated titanium oxide (A) is more enhanced, the aggregation of surface coated titanium oxide (A) in the resin composition can be more reduced, the dispersibility is more enhanced, and there is a tendency that it is possible to obtain favorable dielectric characteristics (high permittivity and low dissipation factor) and heat resistance.

Such a naphthol aralkyl-type cyanate ester compound is more preferably a compound represented by a formula (13).

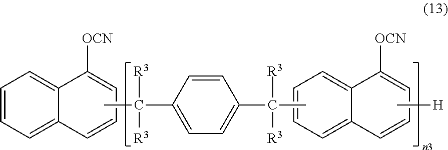

In the formula (13), R³ each independently represents a hydrogen atom or a methyl group, and, in particular, preferably a hydrogen atom. In the formula (13), n3 is an integer of 1 or more, preferably an integer of 1 to 20, and more preferably an integer of 1 to 10.

For the bisphenol A-type cyanate ester compound, one or more selected from the group consisting of 2,2-bis(4-cyanatephenyl)propane and prepolymers of 2,2-bis(4-cyanatephenyl)propane can be used.

Such a bisphenol A-type cyanate ester compound can be a commercial product, and examples include Primaset (registered trademark) BADCy (product name, Lonza K.K., 2,2-bis(4-cyanatephenyl)propane, cyanate ester group equivalent: 139 g/eq.) and CA210 (product name, Mitsubishi Gas Chemical Company, Inc., a prepolymer of 2,2-bis(4-cyanatephenyl)propane, cyanate ester group equivalent: 139 g/eq.).

These cyanate ester compounds can be produced in accordance with a known method. Examples of the specific production method include a method described in Japanese Patent Laid-Open No. 2017-195334 (particularly, paragraphs from 0052 to 0057).

The content of the cyanate ester compound is preferably 1 to 65 parts by mass, more preferably 2 to 60 parts by mass, further preferably 3 to 55 parts by mass, furthermore preferably, 4 to 50 parts by mass, further preferably 5 to 45 parts by mass, and particularly preferably 6 to 40 parts by mass, based on 100 parts by mass of the total resin solid content in the resin composition. When a content of the cyanate ester compound is within the above range, surface coated titanium oxide (A) is even more favorably dispersed, and there is a tendency that it is possible to obtain the resin composition having even more excellent heat resistance and moisture absorption and heat resistance during curing, and further favorable dielectric characteristics (high permittivity and low dissipation factor) and further the insulation layer having an even more suitable surface hardness. When a content of the cyanate ester compound is within the above range, surface coated titanium oxide (A) is even more favorably dispersed, and there is a tendency that it is possible to obtain the resin composition having even more excellent heat resistance and moisture absorption and heat resistance during curing, and further favorable dielectric characteristics (high permittivity and low dissipation factor), and the insulation layer having an even more suitable surface hardness. The close contact with surface coated titanium oxide (A) is more enhanced, the aggregation of surface coated titanium oxide (A) in the resin composition can be more reduced, the dispersibility is more enhanced, and there is a tendency that it is possible to obtain favorable dielectric characteristics (high permittivity and low dissipation factor) and heat resistance.

### (Phenolic Compound)

The resin composition of the present embodiment can contain a phenolic compound. For the phenolic compound, a known compound can be appropriately used as long as the compound has two or more phenolic hydroxy groups in one molecule, and the kind thereof is not particularly limited. The phenolic compounds can be used singly, or two or more thereof can also be used in combination.

Examples of the phenolic compound include cresol novolac-type phenolic resins, biphenyl aralkyl-type phenolic resins represented by the formula (14), naphthol aralkyl-type phenolic resins represented by the formula (15), aminotriazine novolac-type phenolic resins, naphthalene-type phenolic resins, phenol novolac resins, alkylphenol novolac resins, bisphenol A-type novolac resins, dicyclopentadiene-type phenolic resins, ZYLOCK-type phenolic resins, terpene-modified phenolic resins, and polyvinylphenols.

Of these, the phenol compound preferably contains one or more selected from the group consisting of cresol novolac-type phenolic resins, biphenyl aralkyl-type phenolic resins represented by the formula (14), naphthol aralkyl-type phenolic resins represented by the formula (15), aminotriazine novolac-type phenolic resins, and naphthalene-type phenolic resins, and more preferably contains one or more selected from the group consisting of biphenyl aralkyl-type phenolic resins represented by the formula (14) and naphthol aralkyl-type phenolic resins represented by the formula (15), in view of obtaining excellent formability and surface hardness.

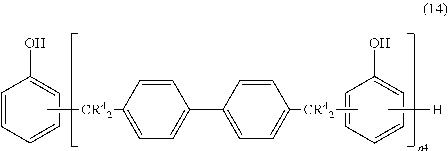

In the formula (14), R⁴ each independently represents a hydrogen atom or a methyl group, and n₄ is an integer of 1 to 10.

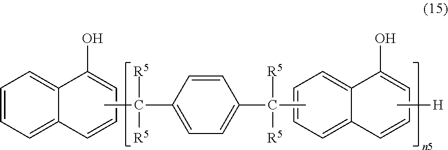

In the formula (15), R⁵ each independently represents a hydrogen atom or a methyl group, and n₅ is an integer of 1 to 10.

The content of the phenol compound is preferably 1 to 50 parts by mass, more preferably 5 to 40 parts by mass, and further preferably 10 to 30 parts by mass, based on 100 parts by mass of the total resin solid content in the resin composition. When a content of the phenol compound is within the above range, the adhesivity, flexibility and the other properties tend to be more excellent.

### (Alkenyl-Substituted Nadiimide Compound)

The resin composition of the present embodiment can contain an alkenyl-substituted nadiimide compounds. The alkenyl-substituted nadiimide compound is not particularly limited as long as the compound has one or more alkenyl-substituted nadiimide groups in a molecule. The alkenyl-substituted nadiimide compounds can be used singly, or two or more thereof can also be used in combination.

Examples of the alkenyl-substituted nadiimide compound include the compound represented by the following formula (2d).

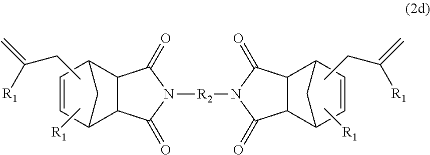

In the formula (2d), R₁ each independently represents a hydrogen atom, or an alkyl group having 1 to 6 carbon atoms (e.g., methyl group or ethyl group), R₂ represents an alkylene group having 1 to 6 carbon atoms, a phenylene group, a biphenylene group, a naphthylene group, or a group represented by a formula (16) or a formula (17).

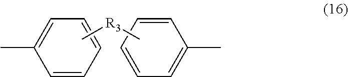

In the formula (16), R₃ represents a methylene group, an isopropylidene group, CO, O, S or SO₂.

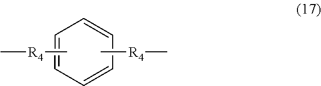

In the formula (17), R₄ each independently represents an alkylene group having 1 to 4 carbon atoms or a cycloalkylene group having 5 to 8 carbon atoms.

The alkenyl-substituted nadiimide compounds represented by the formula (2d) can be a commercial product, or a product produced in accordance with a known method can also be used. Examples of the commercial product include BANI-M and BANI-X (all product names, Maruzen Petrochemical Co., Ltd.).

The content of the alkenyl-substituted nadiimide compound is preferably 1 to 50 parts by mass, more preferably 5 to 40 parts by mass, and further preferably 10 to 30 parts by mass, based on 100 parts by mass of the total resin solid content in the resin composition. When a content of the alkenyl-substituted nadiimide compound is within the above range, the adhesivity, heat resistance and the like tend to be more excellent.

### (Oxetane Resin)

The resin composition of the present embodiment can contain an oxetane resin. Oxetane resin is not particularly limited, and a generally known resin can be used. The oxetane resins can be used singly, or two or more thereof can also be used in combination.

Examples of the oxetane resin include alkyloxetane such as oxetane, 2-methyloxetane, 2,2-dimethyloxetane, 3-methyloxetane, and 3,3-dimethyloxetane, 3-methyl-3-methoxymethyloxetane, 3,3-di(trifluoromethyl)perfluorooxetane, 2-chloromethyloxetane, 3,3-bis(chloromethyl)oxetane, biphenyl-type oxetane, OXT-101 (product name, Toagosei Co., Ltd.), and OXT-121 (product name, Toagosei Co., Ltd.).

The content of the oxetane resin is preferably 1 to 50 parts by mass, more preferably 5 to 40 parts by mass, and further preferably 10 to 30 parts by mass, based on 100 parts by mass of the total resin solid content in the resin composition. When a content of the oxetane resin is within the above range, the adhesivity, flexibility and the other properties tend to be more excellent.

### (Benzoxazine Compound)

The resin composition of the present embodiment can contain a benzoxazine compound. The benzoxazine compound is not particularly limited as long as the compound has two or more dihydrobenzoxazine rings in a molecule, and a generally known compound can be used. The benzoxazine compounds can be used singly, or two or more thereof can also be used in combination.

Examples of the benzoxazine compound include bisphenol A-type benzoxazine BA-BXZ, bisphenol F-type benzoxazine BF-BXZ, and bisphenol S-type benzoxazine BS-BXZ (all product names, Konishi Chemical Ind. Co., Ltd.).

The content of the benzoxazine compound is preferably 1 to 50 parts by mass, more preferably 5 to 40 parts by mass, and further preferably 10 to 30 parts by mass, based on 100 parts by mass of the total resin solid content in the resin composition. When a content of the benzoxazine compound is within the above range, the adhesivity, flexibility and the other properties tend to be more excellent.

### (Compound Having a Polymerizable Unsaturated Group)

The resin composition of the present embodiment can contain a compound having a polymerizable unsaturated group. The compound having a polymerizable unsaturated group is not particularly limited, and a generally known compound can be used. The compounds having a polymerizable unsaturated group can be used singly, or two or more thereof can also be used in combination.

Examples of the compound having a polymerizable unsaturated group include vinyl compounds such as ethylene, propylene, styrene, divinyl benzene, and divinyl biphenyl; meth(acrylates) of monohydric or polyhydric alcohol such as methyl (meth)acrylate, 2-hydroxyethyl (meth)acrylate, 2-hydroxypropyl (meth)acrylate, polypropylene glycol di(meth)acrylate, trimethylolpropane di(meth)acrylate, trimethylolpropane tri(meth)acrylate, pentaerythritol tetra(meth)acrylate, and dipentaerythritol hexa(meth)acrylate; epoxy (meth)acrylates such as bisphenol A-type epoxy (meth)acrylate, and bisphenol F-type epoxy (meth)acrylate; and benzocyclobutene resins.

The content of the compound having a polymerizable unsaturated group is preferably 1 to 50 parts by mass, more preferably 5 to 40 parts by mass, and further preferably 10 to 30 parts by mass, based on 100 parts by mass of the total resin solid content in the resin composition. When a content of the compound having a polymerizable unsaturated group is within the above range, the adhesivity, flexibility and the other properties tend to be more excellent.

### <Filler (C)>

The resin composition of the present embodiment preferably further contains a filler (C) different from surface coated titanium oxide (A), in view of having further dispersibility with surface coated titanium oxide (A) in the resin composition containing surface coated titanium oxide (A) and thermosetting compound (B), and obtaining the resin composition having more excellent heat resistance and moisture absorption and heat resistance during curing, and more favorable dielectric characteristics (high permittivity and low dissipation factor). Filler (C) is not particularly limited as long as it is different from surface coated titanium oxide (A). Fillers (C) can be used singly, or two or more thereof can also be used in combination.

The median particle size (D50) of filler (C) is preferably 0.10 to 10.0 μm, and more preferably 0.30 to 5.0 μm. When a median particle size (D50) is within the above range, even better dispersibility with surface coated titanium oxide (A) is obtained in the resin composition containing surface coated titanium oxide (A) and thermosetting compound (B), and there is a tendency that it is possible to obtain the resin composition having even more excellent heat resistance and moisture absorption and heat resistance during curing, and even more favorable dielectric characteristics (high permittivity and low dissipation factor). The median particle size (D50) of filler (C) is calculated in the same manner as for the median particle size (D50) of surface coated titanium oxide (A) described above.

Examples of filler (C) include inorganic fillers such as silica, silicon compounds (e.g., white carbon), metal oxides (e.g., alumina, titanium white, strontium titanate (SrTiO₃), calcium titanate (CaTiO₃), titanium oxide (TiO₂) different from surface coated titanium oxide (A), MgSiO₄, MgTiO₃, ZnTiO₃, ZnTiO₄, CaTiO₃, SrTiO₃, SrZrO₃, BaTi₂O₅, BaTi₄O₉, Ba₂Ti₉O₂₀, Ba(Ti,Sn)₉O₂₀, ZrTiO₄, (Zr,Sn)TiO₄, BaNd₂Ti₅O₁₄, BaSmTiO₁₄, Bi₂O₃—BaO—Nd₂O₃—TiO₂, La₂Ti₂O₇, barium titanate (BaTiO₃), Ba(Ti,Zr)O₃, (Ba,Sr)TiO₃, molybdenum compounds (e.g., molybdic acid, zinc molybdates such as ZnMoO₄ and Zn₃Mo₂O₉, ammonium molybdate, sodium molybdate, potassium molybdate, calcium molybdate, molybdenum disulfide, molybdenum trioxide, molybdic acid hydrates, and ammonium zinc molybdate hydrates such as (NH₄) Zn₂Mo₂O₉·(H₃O)), zinc oxide, magnesium oxide, and zirconium oxide), metal nitrides (e.g., boron nitride, silicon nitride, and aluminum nitride), metal sulfates (e.g., barium sulfate), metal hydroxides (e.g., aluminum hydroxide, heated products of aluminum hydroxide (e.g., those obtained by heat treating aluminum hydroxide and reducing a part of water of crystallization), boehmite, and magnesium hydroxide), zinc compounds (e.g., zinc borate and zinc stannate), clay, kaolin, talc, calcined clay, calcined kaolin, mica, E-glass, A-glass, NE-glass, C-glass, L-glass, D-glass, S-glass, M-glass G20, glass short fibers (including glass fine powders such as E glass, T glass, D glass, S glass, and Q glass), hollow glass, spherical glass, and metal microparticles formed by insulating a metal such as gold, silver, palladium, copper, nickel, iron, cobalt, zinc, Mn—Mg—Zn, Ni—Zn, Mn—Zn, carbonyl iron, Fe—Si, Fe—Al—Si, and Fe—Ni; and organic fillers, including powders of rubbers such as styrene-based, butadiene-based, and acryl-based rubbers; core/shell rubber powder; silicone resin powder; silicone rubber powder; and silicone composite powder.

Of these, filler (C) preferably contains one or more selected from the group consisting of silica, alumina, barium titanate, strontium titanate, calcium titanate, aluminum nitride, boron nitride, boehmite, aluminum hydroxide, zinc molybdate, silicone rubber powder, and silicone-composite powder, more preferably contains one or more selected from the group consisting of silica, talc, and zinc molybdate, and further preferably contains silica, in view of having further dispersibility with surface coated titanium oxide (A) in the resin composition containing surface coated titanium oxide (A) and thermosetting compound (B), and obtaining the resin composition having even more excellent heat resistance and moisture absorption and heat resistance during curing, and even more favorable dielectric characteristics (high permittivity and low dissipation factor).

Examples of the silica include natural silica, fused silica, synthetic silica, fumed silica, and hollow silica. When the resin composition contains the silica, processability tends to be more excellent. These silicas can be used singly, or two or more thereof can also be used in combination. Of these, one or more selected from the group consisting of fused silica and hollow silica are preferable, in view of having a low coefficient of thermal expansion, and excellent dispersibility in the resin composition.

Silica can be a commercial product, and examples include SC2050-MB, SC5050-MOB, SC2500-SQ, SC4500-SQ, SC4053-SQ, and SC5050-MOB (all product names, Admatechs Company Limited); and SFP-130MC (product name, Denka Company Limited).

The filler (C) can be the surface treated filler in which an inorganic oxide is formed on at least a part of the surface of the core particle of the filler. Examples of such a filler include the surface treated molybdenum compound particle (support type) in which an inorganic oxide is formed on at least a part of the surface of core particle made of a molybdenum compound.

The inorganic oxide can be provided on at least a part of the surface of the core particle of the filler. The inorganic oxide can be provided partially on the surface of the core particle of the filler, or can be provided so as to cover the entire surface of the core particle of the filler. In view of obtaining the printed wiring board or the like having more favorable heat resistance and moisture absorption and heat resistance, and more favorable dielectric characteristics (high permittivity and low dissipation factor), it is preferable that the inorganic oxide be uniformly provided so as to cover the entire surface of the core particle of the filler, and specifically, that a film of an inorganic oxide be uniformly formed on the surface of the core particle of the filler.

The inorganic oxide is preferably those with excellent heat resistance. The kind thereof is not particularly limited, but a metal oxide is more preferable. Examples of the metal oxide include SiO₂, Al₂O₃, TiO₂, ZnO, In₂O₃, SnO₂, NiO, CoO, V₂O₅, CuO, MgO, and ZrO₂. These can be used singly, or two or more thereof can be appropriately used in combination. Of these, the metal oxide is preferably one or more selected from the group consisting of silica (SiO₂), titania (TiO₂), alumina (Al₂O₃), and zirconia (ZrO₂), and more preferably silica, in view of heat resistance, insulation characteristic, and cost, for example.

The thickness of the inorganic oxide on the surface can be appropriately set in accordance with desired performances and is not particularly limited. The thickness thereof is preferably 3 to 500 nm, more preferably 5 to 200 nm, and further preferably 10 to 100 nm, in view of forming a uniform film of the inorganic oxide to provide more favorable close contact with the core particle of the filler, and obtaining the printed wiring board or the like having more favorable heat resistance and moisture absorption and heat resistance, and more favorable dielectric characteristics (high permittivity and low dissipation factor).

Examples of the surface treated molybdenum particle (supported type) include those obtained by surface treating particles of a molybdenum compound with a silane coupling agent, and those obtained by treating the surface thereof with an inorganic oxide by the sol-gel method, liquid phase deposition method, or the like.

For the surface treated molybdenum compound particles, it is preferable that the inorganic oxide be provided on at least a part of the surface or the entire surface, and specifically at least on a part or the whole of the outer circumference of the core particle made of the molybdenum compound. Of such surface treated molybdenum compounds particles, it is more preferable that silica as the inorganic oxide is provided on at least a part of the surface or the entire surface, and specifically at least on a part or the whole of the outer circumference of core particles made of the molybdenum compound. The core particle made of the molybdenum compound is more preferably at least one selected from the group consisting of molybdic acid, zinc molybdate, and ammonium zinc molybdate hydrates, and further preferably zinc molybdate.

In view of the dispersibility in resin composition, the median particle size (D50) of the surface treated molybdenum compound particles is preferably 0.1 to 10 μm, more preferably 0.5 to 8 μm, further preferably 1 to 4 μm, and furthermore preferably 1 to 3 μm. The median particle size (D50) of the surface treated molybdenum compound particles is calculated in the same manner as for the median particle size (D50) of surface coated titanium oxide (A) described above.

The core particle made of the molybdenum compound can be produced by various known methods such as crushing method and granulation method, and the production method thereof is not particularly limited. Additionally, a commercial product thereof can be used.

The production method of the surface treated molybdenum compound particle is not particularly limited, and various know techniques, including the sol-gel method, liquid phase deposition method, dip coating method, spray coating method, printing method, electroless plating method, sputtering method, vapor deposition method, ion plating method, and CVD method, can be appropriately employed to provide the inorganic oxide or a precursor thereof on the surface of the core particle made of the molybdenum compound, whereby the surface treated molybdenum compound particles can be obtained. The method for providing the inorganic oxide or a precursor thereof on the surface of the core particle made of the molybdenum compound can be either a wet method or a dry method.

A preferable example of the production method of the surface treated molybdenum compound particle is as follows: the molybdenum compound (core particles) is dispersed in a solution obtained by dissolving a metal alkoxide such as silicon alkoxide (alkoxysilane) or aluminum alkoxide in an alcohol; a mixed solution of water, alcohol, and a catalyst is added dropwise thereto while stirring to hydrolyze the alkoxide, thereby forming a film of silicon oxide or aluminum oxide as a low refractive index film on the surface of the compound; and then the resulting powder is collected by solid-liquid separation, vacuum dried, and then heat-treated. Another preferable example of the production method is as follows: the molybdenum compound (core particles) is dispersed in a solution obtained by dissolving a metal alkoxide such as silicon alkoxide or aluminum alkoxide in an alcohol; the resultant is mixed at a high temperature and a low pressure, thereby forming a film of silicon oxide or aluminum oxide on the surface of the compound; and then the resulting powder is vacuum dried and crushed. By these methods, the surface treated molybdenum compound particles having a film of a metal oxide such as silica, alumina or the others on the surface of the molybdenum compound can be obtained.

The content of filler (C) in the resin composition containing surface coated titanium oxide (A) and thermosetting compound (B) is preferably 50 to 300 parts by mass, more preferably 70 to 200 parts by mass, and further preferably 100 to 150 parts by mass, based on 100 parts by mass of the total resin solid content in the resin composition, in view of having better dispersibility with surface coated titanium oxide (A), and obtaining the resin composition having even more excellent heat resistance and moisture absorption and heat resistance during curing, and even more favorable dielectric characteristics (high permittivity and low dissipation factor). When two or more kinds of such fillers (C) are contained, the total amount can be within the above range.

Surface coated titanium oxide (A) and filler (C) are preferably contained in a volume ratio (surface coated titanium oxide (A):filler (C)) ranging from 15:85 to 85:15, more preferably ranging from 20:80 to 80:20, and further preferably ranging from 25:75 to 75:25. When a volume ratio is within the above range, surface coated titanium oxide (A) and filler (C) tend to be still more dispersed in thermosetting compound (B). For this reason, surface coated titanium oxide (A) and filler (C) are not unevenly distributed in the resin composition such as a resin varnish, thereby more inhibiting the water absorption by the titanium oxide and obtaining the printed wiring board or the like having more favorable heat resistance and moisture absorption and heat resistance during curing, and more favorable dielectric characteristics (high permittivity and low dissipation factor) and the insulation layer having more excellent moisture absorption and heat resistance. Additionally, the resin composition has excellent coatability so that a molded article with a good appearance can also be obtained. Further, surface coated titanium oxide (A) and filler (C) are well dispersed in the resin composition, whereby the coefficient of thermal expansion of an insulation layer can be suitably controlled, thereby efficiently forming a dielectric channel. For this reason, the insulation layer having excellent moisture absorption and heat resistance and a low coefficient of thermal expansion, and having a high permittivity and a low dissipation factor tends to be suitably obtained.

In the resin composition of the present embodiment, a filler having a high permittivity can be used as filler (C) because such a filler can contribute to, for example, downsizing of a circuit, and downsizing of high frequency electrical components due to an increased capacitance of a capacitor. Examples of the filler include titanium oxide (TiO₂) different from surface coated titanium oxide (A), MgSiO₄, MgTiO₃, ZnTiO₃, ZnTiO₄, CaTiO₃, SrTiO₃, SrZrO₃, BaTi₂O₅, Ba₂Ti₉O₂₀, Ba(Ti,Sn)₉O₂₀, ZrTiO₄, (Zr,Sn)TiO₄, BaNd₂Ti₅O₁₄, BaSmTiO₁₄, Bi₂O₃—BaO—Nd₂O₃—TiO₂, La₂Ti₂O₇, BaTiO₃, Ba(Ti, Zr)O₃, and (Ba,Sr)TiO₃, and metal microparticles formed by insulating a metal such as gold, silver, palladium, copper, nickel, iron, cobalt, zinc, Mn—Mg—Zn, Ni—Zn, Mn—Zn, carbonyl iron, Fe—Si, Fe—Al—Si, and Fe—Ni. These fillers can be used singly, or two or more thereof can also be used in combination.

### <Silane Coupling Agent>

The resin composition of the present embodiment can further contain a silane coupling agent. When the resin composition contains a silane coupling agent, the dispersibility of surface coated titanium oxide (A) and the filler (C) to be blended as needed in the resin composition further enhances, thereby tending to further increase the adhesive strength of each component included in the resin composition to the base material to be described later. The silane coupling agents can be used singly, or two or more thereof can also be used in combination.

The silane coupling agent is not particularly limited, and a silane coupling agent generally used for the surface treatment of an inorganic matter can be used. Examples include aminosilane compounds (e.g., 3-aminopropyltriethoxysilane, and N-β-(aminoethyl)-γ-aminopropyltrimethoxysilane), epoxysilane compounds (e.g., 3-glycidoxy propyltrimethoxysilane), acrylsilane compounds (e.g., γ-acryloxypropyl trimethoxysilane), cationic silane compounds (e.g., N-β-(N-vinylbenzylaminoethyl)-γ-aminopropyltrimethoxysilane hydrochloride), styrylsilane compounds, phenylsilane compounds. The silane coupling agents can be used singly, or two or more thereof can also be used in combination. Of these, the silane coupling agent is preferably one or more selected from the group consisting of epoxysilane compounds and styrylsilane compounds. Examples of the epoxysilane compound include KBM-403, KBM-303, KBM-402, and KBE-403 (all product names, Shin-Etsu Chemical Co., Ltd.). Examples of the styrylsilane compound include KBM-1403 (product name, Shin-Etsu Chemical Co., Ltd.).

The content of the silane coupling agent is not particularly limited, and can be 0.1 to 5.0 parts by mass, based on 100 parts by mass of the total resin solid content in the resin composition.

### <Wetting and Dispersing Agent>

The resin composition of the present embodiment can further contain a wetting and dispersing agent. When the resin composition contains a wetting and dispersing agent, the dispersibility of filler (C) tends to be more enhanced. The wetting and dispersing agents can be used singly, or two or more thereof can also be used in combination.

The wetting and dispersing agent can be any known dispersing agent (dispersion stabilizer) used for dispersing filler (C), and examples include DISPER BYK (registered trademark)-110, 111, 118, 180, 161, 2009, 2152, 2155, W996, W9010, W903 (all product names, BYK Japan KK).

The content of the wetting and dispersing agent is not particularly limited, and is preferably 0.5 parts by mass or more and 10 parts by mass or less, based on 100 parts by mass of the total resin solid content in the resin composition.

### <Curing Accelerator>

The resin composition of the present embodiment can further contain a curing accelerator. The curing accelerators can be used singly, or two or more thereof can also be used in combination.

Examples of the curing accelerator include imidazoles such as triphenyl imidazole (e.g., 2,4,5-triphenyl imidazole); organic peroxides such as benzoyl peroxide, lauroyl peroxide, acetyl peroxide, para-chlorobenzoyl peroxide, and di-tert-butyl-di-perphthalate; azo compounds such as azobisnitrile; tertiary amines such as N,N-dimethylbenzylamine, N,N-dimethylaniline, N,N-dimethyltoluidine, 2-N-ethylanilino ethanol, tri-n-butylamine, pyridine, quinoline, N-methylmorpholine, triethanolamine, triethylenediamine, tetramethylbutanediamine, and N-methyl piperidine; phenols such as phenol, xylenol, cresol, resorcin, and catechol; organic metal salts such as lead naphthenate, lead stearate, zinc naphthenate, zinc octylate, manganese octylate, tin oleate, dibutyltin maleate, manganese naphthenate, cobalt naphthenate, and acetylacetone iron; those obtained by dissolving these organic metal salts in a hydroxy group-containing compound such as phenol and bisphenol; inorganic metal salts such as stannous chloride, zinc chloride, and aluminum chloride; organic tin compounds such as dioctyl tin oxide, other alkyl tins, and alkyl tin oxide; and phosphorus compounds such as triphenylphosphine, and phosphonium borate compounds. Of these, triphenyl imidazoles such as 2,4,5-triphenyl imidazole and manganese octylate are preferable because these tend to accelerate the curing reaction to increase the glass transition temperature more.

The content of the curing accelerator is not particularly limited, can be 0.001 parts by mass or more and 1.0 parts by mass or less, based on 100 parts by mass of the total resin solid content in the resin composition.

### <Solvent>

The resin composition of the present embodiment can further contain a solvent. When the resin composition contains a solvent, the viscosity of the resin composition when preparing reduces, the handleability (operability) further enhances, and the penetrating ability into a base material tends to further enhance. The solvents can be used singly, or two or more thereof can also be used in combination.

The solvent is not particularly limited as long as it can dissolve a part or all of each of the components in the resin composition. Examples include ketones (acetone, and methyl ethyl ketones), aromatic hydrocarbons (e.g., toluene, and xylene), amides (e.g., dimethyl formaldehyde), propylene glycol monomethyl ether, and acetate thereof.

### <Other Components>

The resin composition of the present embodiment can contain components other than above as long as expected characteristics are not affected. Examples of flame retardant compound include bromine compounds such as 4,4′-dibromobiphenyl; nitrogen-containing compounds such as ester phosphate, melamine phosphate, melamine, and benzoguanamine; and silicon compounds. Further, examples of various additives include an ultraviolet absorbent, an antioxidant, a photopolymerization initiator, a fluorescent whitening agent, a photosensitizing agent, a dye, a pigment, a thickener, a lubricant, a defoaming agent, a dispersing agent, a leveling agent (a surface conditioner), a brightening agent, and a polymerization inhibitor.

The content of other components is not particularly limited, and typically 0.01 parts by mass or more and 10 parts by mass or less, respectively, based on 100 parts by mass of the total resin solid content in the resin composition.

### [Production Method of Resin Composition]

The production method of the resin composition of the present embodiment is not particularly limited, and, for example, surface coated titanium oxide (A), thermosetting compound (B), and the compounds described above, as needed, may be mixed and thoroughly stirred. During this operation, known treatments such as stirring, mixing and kneading can be carried out to homogeneously dissolve or disperse each of the components. Specifically, when the stirring and dispersing treatments are carried out using a stirring tank equipped with a stirrer having a reasonable stirring ability, the dispersibility of surface coated titanium oxide (A) and the filler (C) to be blended as needed in the resin composition can be enhanced. The above stirring, mixing, and kneading treatments can be appropriately carried out, for example, by using known devices such as a device for the purpose of mixing such as a ball mill, and a bead mill, or a rotation- or revolution-type mixing device.

During the preparation of the resin composition, a solvent is used as needed, so that the resin composition can be prepared in the form of a resin varnish. The kind of the solvent is not particularly limited as long as it can dissolve the resin in the resin composition. Specific examples thereof are as described above. The resin varnish can be obtained typically by adding 10 to 900 parts by mass of a solvent to 100 parts by mass of the components excluding the solvent in the resin, and carrying out the known treatments (stirring, mixing, and kneading treatments). The kind of the solvent is not particularly limited as long as it can dissolve the resin in the resin composition. Specific examples thereof are as described above.

### [Usage]

The resin composition of the present embodiment can be suitably used, for example, as a material for a cured product, a prepreg, a film-like underfill material, a resin sheet, a laminate, a build-up material, a non-conductive film, a metal foil-clad laminate, a printed wiring board, and a fiber-reinforced composite material, or for producing a semiconductor device. Hereinafter, these will be described.

### [Cured Product]

The cured product is obtained by curing the resin composition of the present embodiment. In the production method of the cured product, for example, the resin composition of the present embodiment is fused or dissolved in a solvent, then poured into a mold and cured under typical conditions using heat, light or the like to obtain the cured product. In the case of thermosetting, the curing temperature is preferably in a range from 120 to 300° C., in view of efficiently proceeding the curing and preventing the deterioration of a cured product to be obtained.

### [Prepreg]

The prepreg of the present embodiment contains a base material and the resin composition of the present embodiment penetrating or coating the base material. The prepreg of the present embodiment can be obtained by, for example, allowing the resin composition of the present embodiment (e.g., uncured state (stage A)) to penetrate or coat a base material, and then drying at 120 to 220° C. for about 2 to 15 minutes to semi-cure (stage B). In this case, the amount of the resin composition (including the cured product of the resin composition) adhered to the base material, that is, the amount of the resin composition relative to the total amount of the semi-cured prepreg (including the surface coated titanium oxide (A) and the filler (C) to be blended as needed), is preferably in a range from 20 to 99 mass %. The semi-cured state (stage B) refers that each of the components included in the resin composition has not proactively started reacting (curing) while the resin composition is in a dried state, in other words, the resin composition has been heated to the extent that it is no longer viscous in order to volatilize the solvent, and the semi-cured state encompasses a state in which the resin composition is not cured while the solvent has been simply volatilized even without heating. In the present embodiment, the minimum melt viscosity of the semi-cured state (stage B) is typically 20,000 Pa·s or less. The minimum melt viscosity is, for example, 10 Pa·s or more in terms of the lower limit. In the present embodiment, the minimum melt viscosity is measured by the following method. Specifically, 1 g of a resin powder collected from the resin composition is used as a sample, and a minimum melt viscosity is measured by a rheometer (ARES-G2 (product name), TA Instruments). The minimum melt viscosity of the resin powder herein is measured using a disposable plate having a plate diameter of 25 mm in a range from 40° C. or more and 180° C. or less, under the conditions of a heating rate of 2° C./min, a frequency of 10.0 rad/sec, and a strain of 0.1%.

The base material is not particularly limited as long as it is a base material used for various printed wiring board materials. Examples of the kind of material of the base material include glass fibers (e.g., E-glass, D-glass, L-glass, S-glass, T-glass, Q-glass, UN-glass, and NE-glass), inorganic fibers other than the glass fibers (e.g., quartz), and organic fibers (e.g., polyimide, polyamide, polyester, liquid crystalline polyester, and polytetrafluoroethylene). The form of the base material is not particularly limited, and examples include woven fabrics, unwoven fabrics, rovings, chopped strand mats, and surfacing mats. These base materials can be used singly, or two or more thereof can also be used in combination. Of these base materials, woven fabrics subjected to super fiber opening treatment and filling treatment are preferable in view of the dimensional stability, and glass woven fabrics surface treated with a silane coupling agent such as epoxysilane treatment and aminosilane treatment are preferable, in view of moisture absorption and heat resistance. In view of having favorable dielectric characteristic, glass fibers such as E-glass, L-glass, NE-glass, and Q-glass are preferable.

### [Resin Sheet]

The resin sheet of the present embodiment contains the resin composition of the present embodiment. The resin sheet can also be a resin sheet with a support, which contains a support and a layer formed of the resin composition of the present embodiment disposed on the surface of the support. The resin sheet can be used as a build-up film or dry film solder resist. The production method of the resin sheet is not particularly limited, and examples include a method in which a solution of the resin composition of the present embodiment dissolved in a solvent is applied to (coating) the support and dried to obtain the resin sheet.

Examples of the support include, but not limited to, polyethylene films, polypropylene films, polycarbonate films, polyethylene terephthalate films, ethylene tetrafluoroethylene copolymer films, and mold releasing films obtained by coating the surface of any of these films with a mold release agent, organic film base materials such as polyimide films, conductive foils such as copper foil, and aluminum foil, and plate-like supports such as glass plates, SUS plates, and FRP.

Examples of the coating method (applying method) include a method in which a solution of the resin composition of the present embodiment dissolved in a solvent is applied to the support using a bar coater, a die coater, a doctor blade, or a baker applicator. After drying, the support can be released or etched from the resin sheet with the support, in which the support and the resin composition are laminated, to obtain a single layer sheet (resin sheet). For example, the solution of the resin composition of the present embodiment dissolved in a solvent is fed into a mold having a sheet-like cavity and dried to form a sheet-like shape, thereby to obtain a single layer sheet (resin sheet) without using a support.

In the manufacture of the single layer sheet or the resin sheet with the support according to the present embodiment, the drying conditions for removing the solvent are not particularly limited, but the drying is preferably carried out for 1 to 90 minutes at a temperature of 20 to 200° C., in view of easily removing the solvent in the resin composition and inhibiting the progress of curing while drying. In the single layer sheet or the resin sheet with the support, the resin composition can be used in an uncured state after simply drying the solvent, or can be used in a semi-cured state (stage B) as needed. Further, the thickness of the resin layer of the single layer sheet or the resin sheet with the support according to the present embodiment can be adjusted by the concentration and the coating thickness of the solution of the resin composition of the present embodiment, and not particularly limited, and the thickness is preferably, 0.1 to 500 μm in view of easily removing the solvent when drying.

### [Laminate]

The laminate of the present embodiment contains one or more selected from the group consisting of the prepreg and the resin sheet of the present embodiment. In the case of two or more of the prepregs and the resin sheets are laminated, the resin composition used for each prepreg and resin sheet can be the same or different. In the case of using both prepreg and resin sheet, the resin composition used for these can be the same or different. In the laminate of the present embodiment, the one or more selected from the group consisting of the prepreg and the resin sheet can be in a semi-cured state (stage B) or a completely cured state (stage C).

### [Metal Foil-Clad Laminate]

The metal foil-clad laminate of the present embodiment contains the laminate of the present embodiment and a metal foil disposed on one side or each of both sides of the laminate.

The metal foil-clad laminate can contain at least 1 sheet of the prepreg of the present embodiment and a metal foil laminated on one side or each of both sides of the prepreg.

The metal foil-clad laminate can contain at least 1 resin sheet of the present embodiment and a metal foil laminated on one side or each of both sides of the resin sheet.

In the metal foil-clad laminate of the present embodiment, the resin composition used for each prepreg and resin sheet can be the same or different. In the case of using both prepreg and resin sheet, the resin composition used for these can be the same or different. In the metal foil-clad laminate of the present embodiment, the one or more selected from the group consisting of the prepreg and the resin sheet can be in a semi-cured state or a completely cured state.

In the metal foil-clad laminate of the present embodiment, a metal foil is laminated on one or more selected from the group consisting of the prepreg of the present embodiment and the resin sheet of the present embodiment; however, it is preferable that a metal foil be laminated in such a way as to contact the surface of the one or more selected from the group consisting of the prepreg of the present embodiment and the resin sheet of the present embodiment. “The metal foil be laminated in such a way as to contact the surface of the one or more selected from the group consisting of the prepreg and the resin sheet” means that a layer such as an adhesive layer is not included between the prepreg or resin sheet and the metal foil, but that the prepreg or resin sheet directly contacts the metal foil. Due to this, the peel strength of the metal foil of the metal foil-clad laminate increases, and the insulation reliability of a printed wiring board tends to be enhanced.

The metal foil-clad laminate of the present embodiment can have one or more stacked prepregs and/or resin sheets of the present embodiment and the metal foil(s) disposed on one side or both sides of the prepregs and/or resin sheets. Examples of the production method of the metal foil-clad laminate of the present embodiment include a method in which one or more stacked prepregs and/or resin sheets of the present embodiment, and the metal foil(s) disposed on one side or both sides thereof are laminated. Examples of the formation method include a method typically used when forming a laminate and a multilayer board for a printed wiring board, and more specific examples include a method of laminating using a multistage press machine, a multistage vacuum press machine, a continuous molding machine, or an autoclave molding machine, at a temperature of about 180 to 350° C., for heating time of about 100 to 300 minutes, and a surface pressure of about 20 to 100 kgf/cm².

Further, the prepreg and/or the resin sheet of the present embodiment is laminated in combination with a separately manufactured wiring board for an inner layer to form a multilayer board. In the production method of the multilayer board, for example, copper foils having a thickness of about 35 μm are disposed on both sides of one or more stacked prepregs and/or resin sheets of the present embodiment, and laminated by the above formation method to prepare a copper foil-clad laminate. Then, an inner layer circuit is formed and subjected to blacking treatment to form an inner layer circuit board, and then the inner layer circuit boards and the prepregs and/or resin sheets of the present embodiment are alternately disposed one by one. Further, copper foils are disposed on the outermost layers to laminate under the above conditions, preferably under vacuum, whereby a multilayer board can be manufactured. The metal foil-clad laminate of the present embodiment can be suitably used as a printed wiring board.

### (Metal Foil)

The metal foil is not particularly limited, and examples include a gold foil, a silver foil, a copper foil, a tin foil, a nickel foil, and an aluminum foil. Of these, a copper foil is preferable. The copper foil is not particularly limited as long as it is generally used as a material for a printed wiring board, and examples include copper foils such as a rolled copper foil, and an electrolytic copper foil. Of these, an electrolytic copper foil is preferable, in view of copper foil peel strength and fine wiring formation. The thickness of a copper foil is not particularly limited and can be about 1.5 to 70 μm.

### [Printed Wiring Board]

The printed wiring board of the present embodiment has an insulation layer and a conductor layer disposed on one side or each of both sides of the insulation layer, wherein the insulation layer contains a cured product of the resin composition of the present embodiment. The insulation layer preferably contains at least one of a layer formed of the resin composition of the present embodiment (the layer containing the cured product) and a layer formed of the prepreg (the layer containing the cured product). Such a printed wiring board can be produced according to a usual method, and the production method thereof is not particularly limited. For example, the printed wiring board can be produced by using the metal foil-clad laminate described above. Hereinafter, an example of the production method of the printed wiring board is described.

First, the metal foil-clad laminate described above is provided. Next, the surface of the metal foil-clad laminate is subjected to etching treatment to form an inner layer circuit, thereby manufacturing an inner layer substrate. The surface treatment for increasing the adhesive strength is carried out, as needed, on the inner layer circuit surface of this inner layer substrate, then the required number of sheets of the above prepregs are stacked on the inner layer circuit surface, further a metal foil for an outer layer circuit is stacked on the outside thereof, thereby integrating by heating and pressing. Thus, the multilayer laminate is produced in which the base material and the insulation layer consisting of the cured product of the resin composition of the present embodiment are formed between the inner layer circuit and the metal foil for the outer layer circuit. Subsequently, this multilayer laminate is subjected to drilling for a through-hole or a via hole, then a plated metal film is formed on the wall surface of this hole for conducting the inner layer circuit and the metal foil for the outer layer circuit, further the metal foil for the outer layer circuit is subjected to etching treatment to form the outer layer circuit, whereby the printed wiring board is produced.

The printed wiring board obtained in the above production example has the structure in which the insulation layer and the conductor layer formed on the surface of this insulation layer, wherein the insulation layer contains the cured product of the resin composition according to the present embodiment. That is, the prepreg according to the present embodiment (containing the base material and the cured product of the resin composition of the present embodiment penetrating or coating it) and the layer of the resin composition of the metal foil-clad laminate of the present embodiment (the layer containing the cured product of the resin composition of the present embodiment) are structured by the insulation layer containing the cured product of the resin composition of the present embodiment.

### [Semiconductor Device]

The semiconductor device can be produced by mounting a semiconductor tip at a conductive point on the printed wiring board of the present embodiment. The conductive point herein refers to the point at which an electrical signal is transmitted in the multilayer printed wiring board, and such a place can be either on the surface or in an embedded point. Further, the semiconductor tip is not particularly limited as long as it is an electrical circuit element made of a semiconductor as a material.

The method for mounting a semiconductor tip when producing the semiconductor device is not particularly limited as long as the semiconductor tip effectively functions, and specifically examples include wire-bonding mounting method, flip-chip mounting method, bumpless build-up layer (BBUL) mounting method, anisotropic conductive film (ACE) mounting method, and non-conductive film (NCF) mounting method.

### EXAMPLES

Hereinafter, the present embodiment will be more specifically described by way of examples and comparative examples. The present embodiment is not limited at all by the following examples.

### [Measurement Method of Median Particle Size]

The median particle sizes (D50) of the surface coated titanium oxide and the filler (spherical fused silica) were each calculated by measuring a particle size distribution by the laser diffraction scattering method under the following measurement conditions using a laser diffraction scattering type particle size distribution analyzer (MicrotracMT3300EXII (product name), MicrotracBEL Corp.).

### (Conditions for Measurement Using a Laser Diffraction Scattering Type Particle Size Distribution Analyzer)

### (Surface Coated Titanium Oxide)

Solvent: methyl ethyl ketone, solvent refractive index: 1.33, particle refractive index: 2.72, transmittance: 85±5%.

### (Filler)

Solvent: methyl ethyl ketone, solvent refractive index: 1.33, particle refractive index: 1.45 (spherical fused silica), transmittance: 85±5%.

### [Measurement Method of Mass Reduction Rate of Surface Coated Titanium Oxide]

The mass reduction rate in heating of the surface coated titanium oxide from 30° C. to 300° C. at a heating rate of 10° C./min was measured by the following method. First, each surface coated titanium oxide weighed was placed in an aluminum pan and the mass reduction rate in heating from 30° C. to 300° C. at a heating rate of 10° C./min was measured with a simultaneous thermogravimetric analyzer (TG-DSC, NEXTA STA200 (product name), Hitachi High-Tech Corporation). These results are shown in Table 1.

### [Synthesis Example 1] Synthesis of Naphthol Aralkyl-Type Cyanate Ester Compound (SN495V-CN)

300 g of a naphthol aralkyl-type phenolic resin (in terms of OH group 1.28 mol) (SN495V (product name), OH group (hydroxy group) equivalent: 236 g/eq., new Nippon Steel Chemical Co., Ltd.) and 194.6 g of triethylamine (1.92 mol) (1.5 mol based on 1 mol of hydroxy group) were dissolved in 1800 g of dichloromethane, and the resultant was designated as Solution 1. 125.9 g of cyanogen chloride (2.05 mol) (1.6 mol based on 1 mol of hydroxy group), 293.8 g of dichloromethane, 194.5 g of 36% hydrochloric acid (1.92 mol) (1.5 mol based on 1 mol of hydroxy group), and 1205.9 g of water were stirred while maintaining the solution temperature at −2 to −0.5° C., into which Solution 1 was pored over a period of 30 minutes. After completion of pouring Solution 1, the resulting solution was stirred at the same temperature for 30 minutes, and a solution in which 65 g of triethylamine (0.64 mol) (0.5 mol based on 1 mol of hydroxy group) was dissolved in 65 g of dichloromethane (Solution 2) was poured thereinto over a period of 10 minutes. After completion of pouring Solution 2, the resultant was stirred for 30 minutes at the same temperature, and the reaction was completed. Subsequently, the reaction liquid was allowed to stand for separating the organic phase and the aqueous phase, and the obtained organic phase was washed 5 times with 1300 g of water. An electrical conductivity of waste water at the 5th water-washing was 5 μS/cm, thereby confirming that ionic compounds removable by washing with water were sufficiently removed. The organic phase after washed with water was concentrated under reduced pressure and finally concentrated to dryness at 90° C. for 1 hour, thereby obtaining 331 g of the intended naphthol aralkyl-type cyanate ester compound (SN495V-CN, cyanate ester group equivalent: 261 g/eq., R³ in the above formula (13) are all hydrogen atoms, and n3 is an integer of 1 to 10) (orange color viscous substance). An infrared absorption spectrum of the obtained SN495V-CN showed the absorption at 2250 cm-1 (cyanate ester group), and did not show the absorption of hydroxy group.

### Example 1

A resin varnish was obtained by mixing 8 parts by mass of the naphthol aralkyl-type cyanate ester compound (SN495V-CN, cyanate ester group equivalent: 261 g/eq.) obtained in Synthesis Example 1, 28 parts by mass of 2,2-bis(4-(4-maleimidephenoxy)-phenyl)propane (BMI-80 (product name), K.I Chemical Industry Co., Ltd.), 28 parts by mass of a biphenyl aralkyl-type maleimide compound (MIR-3000-70MT (product name), Nippon Kayaku Co., Ltd.), 12 parts by mass of a naphthalene-type epoxy resin (EPICLON EXA-4032-70M (product name), epoxy equivalent: 150 g/eq., DIC corporation), 24 parts by mass of a modified polyphenylene ether compound (OPE-2St1200 (product name), Mitsubishi Gas Chemical Company, Inc., a compound represented by the formula (7) (a polymer of the formula (7), X representing the formula (8), and —(Y—O)— and —(O—Y)— representing the structural unit of the formula (11)), number average molecular weight 1187, vinyl group equivalent: 590 g/eq., minimum melt viscosity: 1000 Pa·s), 80 parts by mass of surface coated titanium oxide (crystal structure: rutile-type, titanium oxide obtained by surface treating titanium dioxide with silica, alumina, and dimethyl silicone (the total content of silica, alumina, and dimethyl silicone: 3 mass %), titanium oxide content: 97 mass %, median particle size (D50): 0.21 μm, CR-63 (product name), ISHIHARA SANGYO KAISHA, LTD.), 120 parts by mass of spherical fused silica (SC4500-SQ (product name), median particle size (D50): 1.1 μm, Admatechs Company Limited), 4 parts by mass of a silane coupling agent (KBM-1403 (product name), Shin-Etsu Chemical Co., Ltd.), 2 parts by mass of a wetting and dispersing agent (DISPERBYK (registered trademark)-161 (product name), BYK Japan KK), 2 parts by mass of a wetting and dispersing agent (BYK (registered trademark)-W903 (product name), BYK Japan KK), 0.1 parts by mass of 2,4,5-triphenyl imidazole (Tokyo Chemical Industry Co., Ltd.), and 100 parts by mass of methyl ethyl ketone. The blending ratio (content ratio) of the surface coated titanium oxide to the filler (SC4500-SQ (product name)) in the resin varnish was 26:74 (surface coated titanium oxide:filler) in a volume ratio.

The obtained resin varnish was allowed to penetrate and coat an E glass cloth (1031NT S640 (product name), Arisawa Mfg. Co., Ltd.) having a thickness of 0.094 mm and heated to dry at 130° C. for 3 minutes, thereby obtaining a prepreg having a thickness of 0.1 mm. Next, electrolytic copper foils (3EC-M3-VLP (product name), MITSUI MINING & SMELTING CO., LTD.) having a thickness of 12 μm were disposed on the upper and lower sides of the obtained prepreg, and laminated by vacuum pressing at a surface pressure of 30 kgf/cm² and a temperature of 220° C. for 120 minutes, thereby manufacturing a metal foil-clad laminate (double-sided copper-clad laminated sheet) having a thickness of 0.124 mm. Physical properties of the obtained prepreg and metal foil-clad laminate were measured in accordance with the evaluation methods, and the measurement results were shown in Table 1.

### Example 2

A resin varnish was obtained by mixing 8 parts by mass of the naphthol aralkyl-type cyanate ester compound (SN495V-CN, cyanate ester group equivalent: 261 g/eq.) obtained in Synthesis Example 1, 28 parts by mass of 2,2-bis(4-(4-maleimidephenoxy)-phenyl)propane (BMI-80 (product name), K.I Chemical Industry Co., Ltd.), 28 parts by mass of a biphenyl aralkyl-type maleimide compound (MIR-3000-70MT (product name), Nippon Kayaku Co., Ltd.), 12 parts by mass of a naphthalene-type epoxy resin (EPICLON EXA-4032-70M (product name), epoxy equivalent: 150 g/eq., DIC corporation), 24 parts by mass of a modified polyphenylene ether compound (OPE-2St1200 (product name), Mitsubishi Gas Chemical Company, Inc., a compound represented by the formula (7) (a polymer of the formula (7), X representing the formula (8), and —(Y—O)— and —(O—Y)— representing the structural unit of the formula (11)), number average molecular weight 1187, vinyl group equivalent: 590 g/eq., minimum melt viscosity: 1000 Pa·s), 80 parts by mass of surface coated titanium oxide (crystal structure: rutile-type, titanium oxide obtained by surface treating titanium dioxide with alumina and organosilane (the total content of alumina and organosilane: 2 mass %), titanium oxide content: 98 mass %, median particle size (D50): 0.40 μm, R-22L (product name), SAKAI CHEMICAL INDUSTRY CO., LTD.), 120 parts by mass of spherical fused silica (SC4500-SQ (product name), median particle size (D50): 1.1 μm, Admatechs Company Limited), 4 parts by mass of a silane coupling agent (KBM-1403 (product name), Shin-Etsu Chemical Co., Ltd.), 2 parts by mass of a wetting and dispersing agent (DISPERBYK (registered trademark)-161 (product name), BYK Japan KK), 2 parts by mass of a wetting and dispersing agent (BYK (registered trademark)-W903 (product name), BYK Japan KK), 0.1 parts by mass of 2,4,5-triphenyl imidazole (Tokyo Chemical Industry Co., Ltd.), and 100 parts by mass of methyl ethyl ketone. The blending ratio (content ratio) of the surface coated titanium oxide to the filler (SC4500-SQ (product name)) in the resin varnish was 26:74 (surface coated titanium oxide:filler) in a volume ratio.

The obtained resin varnish was allowed to penetrate and coat an E glass cloth (1031NT S640 (product name), Arisawa Mfg. Co., Ltd.) having a thickness of 0.094 mm and heated to dry at 130° C. for 3 minutes, thereby obtaining a prepreg having a thickness of 0.1 mm. Next, electrolytic copper foils (3EC-M3-VLP (product name), MITSUI MINING & SMELTING CO., LTD.) having a thickness of 12 μm were disposed on the upper and lower sides of the obtained prepreg, and laminated by vacuum pressing at a surface pressure of 30 kgf/cm² and a temperature of 220° C. for 120 minutes, thereby manufacturing a metal foil-clad laminate (double-sided copper-clad laminated sheet) having a thickness of 0.124 mm. Physical properties of the obtained prepreg and metal foil-clad laminate were measured in accordance with the evaluation methods, and the measurement results were shown in Table 1.

### Example 3

A resin varnish was obtained by mixing 8 parts by mass of the naphthol aralkyl-type cyanate ester compound (SN495V-CN, cyanate ester group equivalent: 261 g/eq.) obtained in Synthesis Example 1, 28 parts by mass of 2,2-bis(4-(4-maleimidephenoxy)-phenyl)propane (BMI-80 (product name), K.I Chemical Industry Co., Ltd.), 28 parts by mass of a biphenyl aralkyl-type maleimide compound (MIR-3000-70MT (product name), Nippon Kayaku Co., Ltd.), 12 parts by mass of a naphthalene-type epoxy resin (EPICLON EXA-4032-70M (product name), epoxy equivalent: 150 g/eq., DIC corporation), 24 parts by mass of a modified polyphenylene ether compound (OPE-2St1200 (product name), Mitsubishi Gas Chemical Company, Inc., a compound represented by the formula (7) (a polymer of the formula (7), X representing the formula (8), and —(Y—O)— and —(O—Y)— representing the structural unit of the formula (11)), number average molecular weight 1187, vinyl group equivalent: 590 g/eq., minimum melt viscosity: 1000 Pa·s), 80 parts by mass of surface coated titanium oxide (crystal structure: rutile-type, titanium oxide obtained by surface treating titanium dioxide with alumina and silicone oil (the total content of alumina and silicone oil: 2 mass %), titanium oxide content: 98 mass %, median particle size (D50): 0.20 μm, R-11P (product name), SAKAI CHEMICAL INDUSTRY CO., LTD.), 120 parts by mass of spherical fused silica (SC4500-SQ (product name), median particle size (D50): 1.1 μm, Admatechs Company Limited), 4 parts by mass of a silane coupling agent (KBM-1403 (product name), Shin-Etsu Chemical Co., Ltd.), 2 parts by mass of a wetting and dispersing agent (DISPERBYK (registered trademark)-161 (product name), BYK Japan KK), 2 parts by mass of a wetting and dispersing agent (BYK (registered trademark)-W903 (product name), BYK Japan KK), 0.1 parts by mass of 2,4,5-triphenyl imidazole (Tokyo Chemical Industry Co., Ltd.), and 100 parts by mass of methyl ethyl ketone. The blending ratio (content ratio) of the surface coated titanium oxide to the filler (SC4500-SQ (product name)) in the resin varnish was 26:74 (surface coated titanium oxide:filler) in a volume ratio.

The obtained resin varnish was allowed to penetrate and coat an E glass cloth (1031NT S640 (product name), Arisawa Mfg. Co., Ltd.) having a thickness of 0.094 mm and heated to dry at 130° C. for 3 minutes, thereby obtaining a prepreg having a thickness of 0.1 mm. Next, electrolytic copper foils (3EC-M3-VLP (product name), MITSUI MINING & SMELTING CO., LTD.) having a thickness of 12 μm were disposed on the upper and lower sides of the obtained prepreg, and laminated by vacuum pressing at a surface pressure of 30 kgf/cm² and a temperature of 220° C. for 120 minutes, thereby manufacturing a metal foil-clad laminate (double-sided copper-clad laminated sheet) having a thickness of 0.124 mm. Physical properties of the obtained prepreg and metal foil-clad laminate were measured in accordance with the evaluation methods, and the measurement results were shown in Table 1.

### Example 4

A resin varnish was obtained by mixing 76 parts by mass of a biphenyl aralkyl-type maleimide compound (MIR-3000-70MT (product name), Nippon Kayaku Co., Ltd.), 24 parts by mass of a modified polyphenylene ether compound (OPE-2St1200 (product name), Mitsubishi Gas Chemical Company, Inc., a compound represented by the formula (7) (a polymer of the formula (7), X representing the formula (8), and —(Y—O)— and —(O—Y)— representing the structural unit of the formula (11)), number average molecular weight 1187, vinyl group equivalent: 590 g/eq., minimum melt viscosity: 1000 Pa·s), 80 parts by mass of surface coated titanium oxide (crystal structure: rutile-type, titanium oxide obtained by surface treating titanium dioxide with silica, alumina, and dimethyl silicone (the total content of silica, alumina, and dimethyl silicone: 3 mass %), titanium oxide content: 97 mass %, median particle size (D50): 0.21 μm, CR-63 (product name), ISHIHARA SANGYO KAISHA, LTD.), 120 parts by mass of spherical fused silica (SC4500-SQ (product name), median particle size (D50): 1.1 μm, Admatechs Company Limited), 4 parts by mass of a silane coupling agent (KBM-1403 (product name), Shin-Etsu Chemical Co., Ltd.), 2 parts by mass of a wetting and dispersing agent (DISPERBYK (registered trademark)-161 (product name), BYK Japan KK), 2 parts by mass of a wetting and dispersing agent (BYK (registered trademark)-W903 (product name), BYK Japan KK), 0.1 parts by mass of 2,4,5-triphenyl imidazole (Tokyo Chemical Industry Co., Ltd.), and 100 parts by mass of methyl ethyl ketone. The blending ratio (content ratio) of the surface coated titanium oxide to the filler (SC4500-SQ (product name)) in the resin varnish was 26:74 (surface coated titanium oxide:filler) in a volume ratio.

The obtained resin varnish was allowed to penetrate and coat an E glass cloth (1031NT S640 (product name), Arisawa Mfg. Co., Ltd.) having a thickness of 0.094 mm and heated to dry at 130° C. for 3 minutes, thereby obtaining a prepreg having a thickness of 0.1 mm. Next, electrolytic copper foils (3EC-M3-VLP (product name), MITSUI MINING & SMELTING CO., LTD.) having a thickness of 12 μm were disposed on the upper and lower sides of the obtained prepreg, and laminated by vacuum pressing at a surface pressure of 30 kgf/cm² and a temperature of 220° C. for 120 minutes, thereby manufacturing a metal foil-clad laminate (double-sided copper-clad laminated sheet) having a thickness of 0.124 mm. Physical properties of the obtained prepreg and metal foil-clad laminate were measured in accordance with the evaluation methods, and the measurement results were shown in Table 1.

### Example 5

A resin varnish was obtained by mixing 80 parts by mass of a biphenyl aralkyl-type maleimide compound (MIR-3000-70MT (product name), Nippon Kayaku Co., Ltd.), 20 parts by mass of a naphthalene-type epoxy resin (EPICLON EXA-4032-70M (product name), epoxy equivalent: 150 g/eq., DIC corporation), 80 parts by mass of surface coated titanium oxide (crystal structure: rutile-type, titanium oxide obtained by surface treating titanium dioxide with silica, alumina, and dimethyl silicone (the total content of silica, alumina, and dimethyl silicone: 3 mass %), titanium oxide content: 97 mass %, median particle size (D50): 0.21 μm, CR-63 (product name), ISHIHARA SANGYO KAISHA, LTD.), 120 parts by mass of spherical fused silica (SC4500-SQ (product name), median particle size (D50): 1.1 μm, Admatechs Company Limited), 4 parts by mass of a silane coupling agent (KBM-1403 (product name), Shin-Etsu Chemical Co., Ltd.), 2 parts by mass of a wetting and dispersing agent (DISPERBYK (registered trademark)-161 (product name), BYK Japan KK), 2 parts by mass of a wetting and dispersing agent (BYK (registered trademark)-W903 (product name), BYK Japan KK), 0.1 parts by mass of 2,4,5-triphenyl imidazole (Tokyo Chemical Industry Co., Ltd.), and 100 parts by mass of methyl ethyl ketone. The blending ratio (content ratio) of the surface coated titanium oxide to the filler (SC4500-SQ (product name)) in the resin varnish was 26:74 (surface coated titanium oxide:filler) in a volume ratio.

The obtained resin varnish was allowed to penetrate and coat an E glass cloth (1031NT S640 (product name), Arisawa Mfg. Co., Ltd.) having a thickness of 0.094 mm and heated to dry at 130° C. for 3 minutes, thereby obtaining a prepreg having a thickness of 0.1 mm. Next, electrolytic copper foils (3EC-M3-VLP (product name), MITSUI MINING & SMELTING CO., LTD.) having a thickness of 12 μm were disposed on the upper and lower sides of the obtained prepreg, and laminated by vacuum pressing at a surface pressure of 30 kgf/cm² and a temperature of 220° C. for 120 minutes, thereby manufacturing a metal foil-clad laminate (double-sided copper-clad laminated sheet) having a thickness of 0.124 mm. Physical properties of the obtained prepreg and metal foil-clad laminate were measured in accordance with the evaluation methods, and the measurement results were shown in Table 1.

### Comparative Example 1

A resin varnish was obtained by mixing 8 parts by mass of the naphthol aralkyl-type cyanate ester compound (SN495V-CN, cyanate ester group equivalent: 261 g/eq.) obtained in Synthesis Example 1, 28 parts by mass of 2,2-bis(4-(4-maleimidephenoxy)-phenyl)propane (BMI-80 (product name), K.I Chemical Industry Co., Ltd.), 28 parts by mass of a biphenyl aralkyl-type maleimide compound (MIR-3000-70MT (product name), Nippon Kayaku Co., Ltd.), 12 parts by mass of a naphthalene-type epoxy resin (EPICLON EXA-4032-70M (product name), epoxy equivalent: 150 g/eq., DIC corporation), 24 parts by mass of a modified polyphenylene ether compound (OPE-2St1200 (product name), Mitsubishi Gas Chemical Company, Inc., a compound represented by the formula (7) (a polymer of the formula (7), X representing the formula (8), and —(Y—O)— and —(O—Y)— representing the structural unit of the formula (11)), number average molecular weight 1187, vinyl group equivalent: 590 g/eq., minimum melt viscosity: 1000 Pa·s), 80 parts by mass of surface coated titanium oxide (crystal structure: rutile-type, titanium oxide obtained by surface treating titanium dioxide with silica and alumina (the total content of silica and alumina: 10 mass %), titanium oxide content: 90 mass %, median particle size (D50): 0.28 μm, CR-93 (product name), ISHIHARA SANGYO KAISHA, LTD.), 120 parts by mass of spherical fused silica (SC4500-SQ (product name), median particle size (D50): 1.1 μm, Admatechs Company Limited), 4 parts by mass of a silane coupling agent (KBM-1403 (product name), Shin-Etsu Chemical Co., Ltd.), 2 parts by mass of a wetting and dispersing agent (DISPERBYK (registered trademark)-161 (product name), BYK Japan KK), 2 parts by mass of a wetting and dispersing agent (BYK (registered trademark)-W903 (product name), BYK Japan KK), 0.1 parts by mass of 2,4,5-triphenyl imidazole (Tokyo Chemical Industry Co., Ltd.), and 100 parts by mass of methyl ethyl ketone. The blending ratio (content ratio) of the surface coated titanium oxide to the filler (SC4500-SQ (product name)) in the resin varnish was 26:74 (surface coated titanium oxide:filler) in a volume ratio.

The obtained resin varnish was allowed to penetrate and coat an E glass cloth (1031NT S640 (product name), Arisawa Mfg. Co., Ltd.) having a thickness of 0.094 mm and heated to dry at 130° C. for 3 minutes, thereby obtaining a prepreg having a thickness of 0.124 mm. Next, electrolytic copper foils (3EC-M3-VLP (product name), MITSUI MINING & SMELTING CO., LTD.) having a thickness of 12 μm were disposed on the upper and lower sides of the obtained prepreg, and laminated by vacuum pressing at a surface pressure of 30 kgf/cm² and a temperature of 220° C. for 120 minutes, thereby manufacturing a metal foil-clad laminate (double-sided copper-clad laminated sheet) having a thickness of 0.1 mm. Physical properties of the obtained prepreg and metal foil-clad laminate were measured in accordance with the evaluation methods, and the measurement results were shown in Table 1.

### Comparative Example 2

A resin varnish was obtained by mixing 8 parts by mass of the naphthol aralkyl-type cyanate ester compound (SN495V-CN, cyanate ester group equivalent: 261 g/eq.) obtained in Synthesis Example 1, 28 parts by mass of 2,2-bis(4-(4-maleimidephenoxy)-phenyl)propane (BMI-80 (product name), K.I Chemical Industry Co., Ltd.), 28 parts by mass of a biphenyl aralkyl-type maleimide compound (MIR-3000-70MT (product name), Nippon Kayaku Co., Ltd.), 12 parts by mass of a naphthalene-type epoxy resin (EPICLON EXA-4032-70M (product name), epoxy equivalent: 150 g/eq., DIC corporation), 24 parts by mass of a modified polyphenylene ether compound (OPE-2St1200 (product name), Mitsubishi Gas Chemical Company, Inc., a compound represented by the formula (7) (a polymer of the formula (7), X representing the formula (8), and —(Y—O)— and —(O—Y)— representing the structural unit of the formula (11)), number average molecular weight 1187, vinyl group equivalent: 590 g/eq., minimum melt viscosity: 1000 Pa·s), 80 parts by mass of surface coated titanium oxide (crystal structure: rutile-type, titanium oxide obtained by surface treating titanium dioxide with silica and alumina (the total content of silica and alumina: 15 mass %), titanium oxide content: 85 mass %, median particle size (D50): 0.25 μm, PFC-211 (product name), ISHIHARA SANGYO KAISHA, LTD.), 120 parts by mass of spherical fused silica (SC4500-SQ (product name), median particle size (D50): 1.1 μm, Admatechs Company Limited), 4 parts by mass of a silane coupling agent (KBM-1403 (product name), Shin-Etsu Chemical Co., Ltd.), 2 parts by mass of a wetting and dispersing agent (DISPERBYK (registered trademark)-161 (product name), BYK Japan KK), 2 parts by mass of a wetting and dispersing agent (BYK (registered trademark)-W903 (product name), BYK Japan KK), 0.1 parts by mass of 2,4,5-triphenyl imidazole (Tokyo Chemical Industry Co., Ltd.), and 100 parts by mass of methyl ethyl ketone. The blending ratio (content ratio) of the surface coated titanium oxide to the filler (SC4500-SQ (product name)) in the resin varnish was 26:74 (surface coated titanium oxide:filler) in a volume ratio.

The obtained resin varnish was allowed to penetrate and coat an E glass cloth (1031NT S640 (product name), Arisawa Mfg. Co., Ltd.) having a thickness of 0.094 mm and heated to dry at 130° C. for 3 minutes, thereby obtaining a prepreg having a thickness of 0.1 mm. Next, electrolytic copper foils (3EC-M3-VLP (product name), MITSUI MINING & SMELTING CO., LTD.) having a thickness of 12 μm were disposed on the upper and lower sides of the obtained prepreg, and laminated by vacuum pressing at a surface pressure of 30 kgf/cm² and a temperature of 220° C. for 120 minutes, thereby manufacturing a metal foil-clad laminate (double-sided copper-clad laminated sheet) having a thickness of 0.124 mm. Physical properties of the obtained prepreg and metal foil-clad laminate were measured in accordance with the evaluation methods, and the measurement results were shown in Table 1.

### Comparative Example 3

A resin varnish was obtained by mixing 76 parts by mass of a biphenyl aralkyl-type maleimide compound (MIR-3000-70MT (product name), Nippon Kayaku Co., Ltd.), 24 parts by mass of a modified polyphenylene ether compound (OPE-2St1200 (product name), Mitsubishi Gas Chemical Company, Inc., a compound represented by the formula (7) (a polymer of the formula (7), X representing the formula (8), and —(Y—O)— and —(O—Y)— representing the structural unit of the formula (11)), number average molecular weight 1187, vinyl group equivalent: 590 g/eq., minimum melt viscosity: 1000 Pa·s), 80 parts by mass of surface coated titanium oxide (crystal structure: rutile-type, titanium oxide obtained by surface treating titanium dioxide with silica and alumina (the total content of silica and alumina: 15 mass %), titanium oxide content: 85 mass %, median particle size (D50): 0.25 μm, PFC-211 (product name), ISHIHARA SANGYO KAISHA, LTD.), 120 parts by mass of spherical fused silica (SC4500-SQ (product name), median particle size (D50): 1.1 μm, Admatechs Company Limited), 4 parts by mass of a silane coupling agent (KBM-1403 (product name), Shin-Etsu Chemical Co., Ltd.), 2 parts by mass of a wetting and dispersing agent (DISPERBYK (registered trademark)-161 (product name), BYK Japan KK), 2 parts by mass of a wetting and dispersing agent (BYK (registered trademark)-W903 (product name), BYK Japan KK), 0.1 parts by mass of 2,4,5-triphenyl imidazole (Tokyo Chemical Industry Co., Ltd.), and 100 parts by mass of methyl ethyl ketone. The blending ratio (content ratio) of the surface coated titanium oxide to the filler (SC4500-SQ (product name)) in the resin varnish was 26:74 (surface coated titanium oxide:filler) in a volume ratio.

The obtained resin varnish was allowed to penetrate and coat an E glass cloth (1031NT S640 (product name), Arisawa Mfg. Co., Ltd.) having a thickness of 0.094 mm and heated to dry at 130° C. for 3 minutes, thereby obtaining a prepreg having a thickness of 0.1 mm. Next, electrolytic copper foils (3EC-M3-VLP (product name), MITSUI MINING & SMELTING CO., LTD.) having a thickness of 12 μm were disposed on the upper and lower sides of the obtained prepreg, and laminated by vacuum pressing at a surface pressure of 30 kgf/cm² and a temperature of 220° C. for 120 minutes, thereby manufacturing a metal foil-clad laminate (double-sided copper-clad laminated sheet) having a thickness of 0.124 mm. Physical properties of the obtained prepreg and metal foil-clad laminate were measured in accordance with the evaluation methods, and the measurement results were shown in Table 1.

### Comparative Example 4

A prepreg was manufactured in the same manner as in Example 1, except that 80 parts by mass of surface coated titanium oxide (titanium oxide particle 41 mass %, silica 57 mass %, alkylsilane 2 mass %, inorganic matter particle including a plurality of titanium oxide particles therein, median particle size (D50): 4.5 μm, SUNSIL-Tin50AS (product name), Linden Co., Ltd.) was used instead of 80 parts by mass of surface coated titanium oxide (crystal structure: rutile-type, titanium oxide obtained by surface treating titanium dioxide with silica, alumina, and dimethyl silicone (the total content of silica, alumina, and dimethyl silicone: 3 mass %), titanium oxide content: 97 mass %, median particle size (D50): 0.21 μm, CR-63 (product name), ISHIHARA SANGYO KAISHA, LTD.). The blending ratio (content ratio) of the surface coated titanium oxide to the filler (SC4500-SQ (product name)) in the resin varnish was 26:74 (surface coated titanium oxide:filler) in a volume ratio. A metal foil-clad laminate was tried to be manufactured with the obtained prepreg, but it was not possible to manufacture such a metal foil-clad laminate due to formation of voids on the entire surface of such a metal foil-clad laminate.

### Comparative Example 5

A prepreg was manufactured in the same manner as in Example 1, except that 80 parts by mass of surface coated titanium oxide (titanium oxide obtained by surface treating titanium dioxide with silica and alumina, titanium oxide content: 91 mass %, median particle size (D50): 0.20 μm, R-21 (product name), SAKAI CHEMICAL INDUSTRY CO., LTD.) was used instead of 80 parts by mass of surface coated titanium oxide (crystal structure: rutile-type, titanium oxide obtained by surface treating titanium dioxide with silica, alumina, and dimethyl silicone (the total content of silica, alumina, and dimethyl silicone: 3 mass %), titanium oxide content: 97 mass %, median particle size (D50): 0.21 μm, CR-63 (product name), ISHIHARA SANGYO KAISHA, LTD.). The blending ratio (content ratio) of the surface coated titanium oxide to the filler (SC4500-SQ (product name)) in the resin varnish was 26:74 (surface coated titanium oxide:filler) in a volume ratio.

A metal foil-clad laminate was tried to be manufactured with the obtained prepreg, but it was not possible to manufacture such a metal foil-clad laminate due to formation of voids on the entire surface of such a metal foil-clad laminate.

### [Evaluation Methods]

(1) Relative permittivity (Dk) and dissipation factor (Df)

All the copper foils on both sides of the metal foil-clad laminates obtained in Examples and Comparative Examples were etched, thereby obtaining unclad laminates having a thickness of 0.1 mm from which all the copper foils on both sides were removed. The unclad laminate was cut (downsized) to a size of 1 mm×65 mm, thereby obtaining a sample for measurement.

On this sample for measurement, the relative permittivity (Dk) and dissipation factor (Df) at 10 GHz were each measured using a network analyzer (Agilent 8722ES (product name), Agilent Technologies, Inc.). The measurement of the relative permittivity (Dk) and dissipation factor (Df) was carried out under the environment at a temperature of 23° C.±1° C., and a humidity of 50% RH (relative humidity)±5% RH.

Next, the sample for measurement was dried in a dryer at 120° C. for 1 hour. The sample for measurement after drying was subjected to moisture absorption treatment in a thermo-hygrostat (FX-222P (product name), Kusumoto Chemicals, Ltd.) at a temperature of 85° C.±1° C. and a humidity of 85% RH±5% RH for 168 hours. On the sample for measurement after moisture absorption treatment for 168 hours, the relative permittivity (Dk) and the dissipation factor (Df) at 10 GHz were each measured using a network analyzer (Agilent 8722ES (product name), Agilent Technologies, Inc.).

### (2) Moisture Absorption and Heat Resistance Evaluation

Ultrathin copper foils with carrier (MT18FL (product name), MITSUI MINING & SMELTING CO., LTD., thickness: 1.5 μm) were disposed on the upper and lower sides of the prepregs obtained in Examples and Comparative Examples, and laminated by vacuum pressing at a surface pressure of 30 kgf/cm² and a temperature of 220° C. for 120 minutes, thereby manufacturing a metal foil-clad laminate (a double-sided copper-clad laminated sheet) having a thickness of 0.1 mm. Next, all the copper foils on both sides were etched, thereby obtaining unclad laminates from which all the copper foils on both sides were removed. Prepregs having a thickness of 0.06 mm (GHPL-970LF (LD) (product name), MITSUBISHI GAS CHEMICAL COMPANY, INC.) were disposed on the upper and lower sides of this unclad laminate, electrolytic copper foils (3EC-M3-VLP (product name), MITSUI MINING & SMELTING CO., LTD.) having a thickness of 12 μm were further disposed on the upper and lower sides thereof. Lamination was carried out by vacuum pressing at a surface pressure of 30 kgf/cm² and a temperature of 220° C. for 120 minutes, thereby manufacturing a metal foil-clad laminate (double-sided copper-clad laminated sheet) having a thickness of 0.22 mm. The obtained laminate was cut (downsized) to a size of 50 mm×50 mm. The copper foils on one side were all etched and removed, and on the other side the copper foil on a half of the surface was etched and removed, thereby manufacturing a sample for measurement. The obtained sample for measurement was treated for 2 hours, using a pressure cooker test chamber (PC-3 type (product name), HIRAYAMA Manufacturing Corporation), at 121° C. and in the presence of saturated water vapor at 2 atmospheric pressure, and then further dipped for 60 seconds in a solder bath at 280° C. to visually observe the presence or absence of abnormality in appearance changes. For each of the measurement, 5 samples were tested, the case where zero or 1 out of 5 samples had appearance abnormality was rated as “AA”, the case where 2 to 3 samples had appearance abnormality was rated as “BB” and the case where 4 to 5 samples had appearance abnormality was rated as “CC”, and the results were shown in Table 1. In the case where, for example, swells were caused on the copper foil surface or the back of the sample after dipping, it was determined that the sample had appearance abnormality. In the Table, the “PCT 2.0 h” shows the results after the 2 hour-treatment using a pressure cooker test chamber.

### (3) Copper-Clad Solder Heat Resistance

Two sheets of the prepregs obtained in Examples and Comparative Examples were laminated, and electrolytic copper foils (3EC-M3-VLP (product name), MITSUI MINING & SMELTING CO., LTD.) having a thickness of 12 μm were disposed on the upper and lower sides thereof. Lamination was carried out by vacuum pressing at a surface pressure of 30 kgf/cm² and a temperature of 220° C. for 120 minutes, thereby manufacturing a metal foil-clad laminate (double-sided copper-clad laminated sheet) having a thickness of 0.2 mm. The metal foil-clad laminate was cut (downsized) to a size of 50 mm×50 mm, thereby obtaining a sample for measurement. Five samples for measurement in total were manufactured in the same manner. The samples for measurement were floated in a solder bath at 300° C. so that only one side of the sample contacted the solder for 30 minutes. Thirty minutes later, the sample was taken out of the solder bath to visually observe the side contacted the solder of these samples in terms of the presence or absence in appearance changes. Five samples were each observed. As a result, the case where 0 to 1 sample had appearance abnormality was rated as “AA” and the case where 2 to 5 samples had appearance abnormality was rated as “CC”, and the results were shown in Table 1. In the case where, for example, swells were caused on the copper foil surface or the back of the sample taken out from the solder bath, it was determined the sample had appearance abnormality.

TABLE 1

| | | | | | | | | | Compar- |
|---|---|---|---|---|---|---|---|---|---|
| | | | | Exam- | Exam- | Exam- | Exam- | Exam- | ative |
| | | | | ple | ple | ple | ple | ple | Exam- |
| | | | | 1 | 2 | 3 | 4 | 5 | ple 1 |
| Various | Mass reduction rate [%] of surface | | | 0.40 | 0.28 | 0.41 | 0.40 | 0.40 | 0.99 |
| physical | coated titanium oxide | | | | | | | | |
| properties | Relative | | Moisture absorption | 4.9 | 4.9 | 5.0 | 5.0 | 5.1 | 5.0 |
| | permittivity [Dk, | | treatment 0 h | | | | | | |
| | 10 GHz] | | Moisture absorption | 5.0 | 5.1 | 5.2 | 5.1 | 5.3 | 5.1 |
| | | | treatment 168 h | | | | | | |
| | Relative | | Moisture absorption | 0.010 | 0.010 | 0.009 | 0.009 | 0.009 | 0.010 |
| | permittivity [Dk, | | treatment 0 h | | | | | | |
| | 10 GHz] | | Moisture absorption | 0.013 | 0.014 | 0.014 | 0.014 | 0.016 | 0.016 |
| | | | treatment 168 h | | | | | | |
| | Moisture | | Dipping at 280° C. for | AA | AA | AA | AA | AA | BB |
| | absorption | PCT | 60 seconds | | | | | | |
| | and heat | 2.0 h | | | | | | | |
| | resistance | | | | | | | | |

| | | | | | | | |
|---|---|---|---|---|---|---|---|
| Copper-clad | Floating at 300° C. for | AA | AA | AA | AA | AA | CC |
| solder heat | 30 minutes | | | | | | |
| resistance | | | | | | | |

| | | | Compar- | Compar- | Compar- | Compar- |
|---|---|---|---|---|---|---|
| | | | ative | ative | ative | ative |
| | | | Exam- | Exam- | Exam- | Exam- |
| | | | ple 2 | ple 3 | ple 4 | ple 5 |
| Various | Mass reduction rate [%] of surface | | 2.57 | 2.57 | 4.80 | 1.20 |
| physical | coated titanium oxide | | | | | |
| properties | Relative | Moisture absorption | 4.8 | 4.8 | — | — |
| | permittivity [Dk, | treatment 0 h | | | | |
| | 10 GHz] | Moisture absorption | 5.0 | 5.0 | — | — |

| | | treatment 168 h | | | | |
|---|---|---|---|---|---|---|
| Relative | | Moisture absorption | 0.010 | 0.010 | — | — |
| permittivity [Dk, | | treatment 0 h | | | | |
| 10 GHz] | | Moisture absorption | 0.017 | 0.017 | — | — |
| | | treatment 168 h | | | | |
| Moisture | | Dipping at 280° C. for | CC | BB | — | — |
| absorption | PCT | 60 seconds | | | | |
| and heat | 2.0 h | | | | | |
| resistance | | | | | | |

| | | | | | |
|---|---|---|---|---|---|
| Copper-clad | Floating at 300° C. for | CC | CC | — | — |
| solder heat | 30 minutes | | | | |
| resistance | | | | | |

The present application is based on the Japanese Patent Application (No. 2022-46294) filed on Mar. 23, 2022, and the contents of which are incorporated herein by reference.

### INDUSTRIAL APPLICABILITY

The resin composition of the present embodiment can be suitably used as a material for a cured product, a prepreg, a film-like underfill material, a resin sheet, a laminate, a build-up material, a non-conductive film, a metal foil-clad laminate, a printed wiring board, and a fiber-reinforced composite material, or for producing a semiconductor device.

1. A resin composition comprising:
(A) a surface coated titanium oxide in which a mass reduction rate in heating from 30° C. to 300° C. at a heating rate of 10° C./min is 0.5 mass % or less, and
(B) a thermosetting compound.

2. The resin composition according to claim 1, wherein the surface coated titanium oxide (A) has an organic layer and/or an inorganic oxide layer on the surface of a titanium oxide particle.

3. The resin composition according to claim 2, wherein the surface coated titanium oxide (A) further has the organic layer on the surface of the inorganic oxide layer.

4. The resin composition according to claim 2, wherein a total amount of the organic layer and the inorganic oxide layer is 0.1 to 10 mass % based on 100 mass % of the surface coated titanium oxide (A).

5. The resin composition according to claim 2, wherein the inorganic oxide layer is one or more selected from the group consisting of a layer comprising silica, a layer comprising zirconia, and a layer comprising alumina.

6. The resin composition according to claim 2, wherein the organic layer is a layer obtained by surface treating with an organosilicon compound.

7. The resin composition according to claim 6, wherein the organosilicon compound comprises one or more selected from the group consisting of silane coupling agents, organosilane, and organopolysiloxane.

8. The resin composition according to claim 2, wherein a content of the titanium oxide in the surface coated titanium oxide (A) is 90 to 99.9 mass % based on 100 mass % of the surface coated titanium oxide (A).

9. The resin composition according to claim 1, wherein a content of the surface coated titanium oxide (A) is 50 to 500 parts by mass, based on 100 parts by mass of a total resin solid content in the resin composition.

10. The resin composition according to claim 1, wherein the thermosetting compound (B) comprises one or more selected from the group consisting of maleimide compounds, epoxy compounds, modified polyphenylene ether compounds, cyanate ester compounds, phenol compounds, alkenyl-substituted nadiimide compounds, oxetane resins, benzoxazine compounds, and compounds having a polymerizable unsaturated group.

11. The resin composition according to claim 10, wherein the maleimide compound comprises one or more selected from the group consisting of bis(4-maleimidephenyl)methane, 2,2-bis(4-(4-maleimidephenoxy)-phenyl)propane, bis(3-ethyl-5-methyl-4-maleimidephenyl)methane, maleimide compounds represented by the following formula (1), and maleimide compounds represented by the following formula (2): 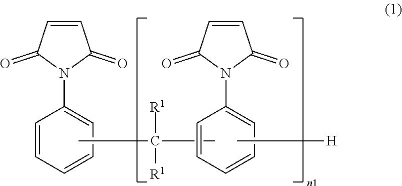
wherein R¹ each independently represents a hydrogen atom or a methyl group, and n1 is an integer of 1 to 10; 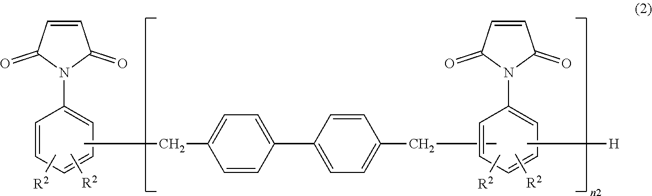
wherein R² each independently represents a hydrogen atom, an alkyl group having 1 to 5 carbon atoms, or a phenyl group, and n2 is an average value and represents 1<n2≤5.

12. The resin composition according to claim 10, wherein the epoxy compound comprises one or more selected from the group consisting of biphenyl aralkyl-type epoxy resins, naphthalene-type epoxy resins, and naphthylene ether-type epoxy resins.

13. The resin composition according to claim 10, wherein the modified polyphenylene ether compound comprises a compound represented by the following formula (3): 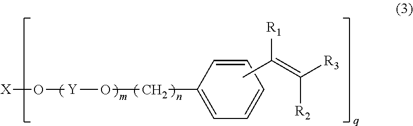
wherein X represents an aromatic group, —(Y—O)m- represents a polyphenylene ether moiety, R₁, R₂, and R₃ each independently represent a hydrogen atom, an alkyl group, an alkenyl group, or an alkynyl group, m represents an integer of 1 to 100, n represents an integer of 1 to 6, and q represents an integer of 1 to 4.

14. The resin composition according to claim 10, wherein the cyanate ester compound comprises one or more selected from the group consisting of phenol novolac-type cyanate ester compounds, naphthol aralkyl-type cyanate ester compounds, naphthylene ether-type cyanate ester compounds, xylene resin-type cyanate ester compounds, bisphenol M-type cyanate ester compounds, bisphenol A-type cyanate ester compounds, diallylbisphenol A-type cyanate ester compounds, bisphenol E-type cyanate ester compounds, bisphenol F-type cyanate ester compounds, and biphenyl aralkyl-type cyanate ester compounds, and prepolymers or polymers of these cyanate ester compounds.

15. The resin composition according to claim 1, further comprising a filler (C) different from the surface coated titanium oxide (A).

16. The resin composition according to claim 15, wherein the filler (C) comprises one or more selected from the group consisting of silica, alumina, barium titanate, strontium titanate, calcium titanate, aluminum nitride, boron nitride, boehmite, aluminum hydroxide, zinc molybdate, silicone rubber powder, and silicone-composite powder.

17. The resin composition according to claim 15, wherein a content of the filler (C) is 50 to 300 parts by mass, based on 100 parts by mass of a total resin solid content in the resin composition.

18. The resin composition according to claim 1, wherein the resin composition is for a printed wiring board.

19. A prepreg, comprising:
abase material, and
the resin composition according to claim 1 penetrating or coating the base material.

20. A resin sheet comprising the resin composition according to claim 1.

21. A laminate comprising the prepreg according to claim 19.

22. A laminate comprising the resin sheet according to claim 20.

23. A metal foil-clad laminate, comprising:
the laminate according to claim 21, and
a metal foil disposed on one side or each of both sides of the laminate.

24. A metal foil-clad laminate, comprising:
the laminate according to claim 22, and
a metal foil disposed on one side or each of both sides of the laminate.

25. A printed wiring board, comprising:
an insulation layer, and
a conductor layer disposed on one side or each of both sides of the insulation layer,
wherein the insulation layer comprises a cured product of the resin composition according to claim 1.
